(19) United States
(12) Patent Application Publication
(10) Pub. No.: US 2024/0339580 A1
(43) Pub. Date: Oct. 10, 2024

(54) IMPLEMENTING A CONDUCTIVE TRACE AND A LIGHT-EMITTING DIODE (LED) ON A CARRIER STRUCTURE VIA SURFACE-MOUNT TECHNOLOGIES (SMT) AND LASER DIRECT STRUCTURING (LDS)

(71) Applicant: Meta Platforms Technologies, LLC, Menlo Park, CA (US)

(72) Inventors: Le CHANG, Bellevue, WA (US); Jason HOWARD, Alpharetta, GA (US); Gregory Alan ROBERTS, Oakland, CA (US); Karthik KADIRVEL, Cupertino, CA (US); Bradley SPARE, San Jose, CA (US); Ankur GUPTA, Redwood City, CA (US); Yang WANG, San Jose, CA (US); Tianren XU, San Jose, CA (US); Peter Eli RENNER, San Jose, CA (US); Tao ZHOU, San Jose, CA (US); Umar AZAD, San Jose, CA (US); Eswarappa CHANNABASAPPA, Milpitas, CA (US)

(73) Assignee: Meta Platforms Technologies, LLC, Menlo Park, CA (US)

(21) Appl. No.: 18/589,014

(22) Filed: Feb. 27, 2024

Related U.S. Application Data
(60) Provisional application No. 63/603,951, filed on Nov. 29, 2023.
(60) Provisional application No. 63/460,224, filed on Apr. 18, 2023.
(60) Provisional application No. 63/458,263, filed on Apr. 10, 2023.

(51) Int. Cl. H01L 33/62; G02B 27/01

(52) U.S. Cl. CPC H01L 33/62; G02B 2027/0138; G02B 27/0172; H01L 2933/0066

(57) ABSTRACT

According to examples, systems and methods for implementing a conductive trace via laser direct structuring (LDS) and a light-emitting diode (LED) via surface-mount technology (SMT) on a carrier structure of a display device are described. A method may include printing a conductive trace onto a carrier, mounted a light-emitting diode (LED) onto the carrier, and attaching a flexible printed circuit (FPC) to the carrier, wherein the light-emitting diode (LED) is communicatively coupled to the flexible printed circuit (FPC) via the conductive trace.

### PRIORITY

This patent application claims priority to U.S. Provisional Patent Application No. 63/458,263, entitled “Wearable Device with Integrated Antennas,” filed on Apr. 10, 2023, U.S. Provisional Patent Application No. 63/460,224, entitled “Providing a Battery Management Unit (BMU) in between a Battery Cell and an Edge of a Temple Arm of a Display Device,” filed on Apr. 18, 2023, and U.S. Provisional Patent Application No. 63/603,951, entitled “Implementing a Conductive Trace and a Light-emitting Diode (LED) on a Carrier Structure via Surface-Mount Technologies (SMT) and Laser Direct Structuring (LDS),” filed on Nov. 29, 2023, the disclosures of which are hereby incorporated by reference in their entireties.

### TECHNICAL FIELD

This patent application relates generally to display technologies, and more specifically, to implementing a conductive trace via laser direct structuring (LDS) and a light-emitting diode (LED) via surface-mount technology (SMT) on a carrier structure of a display device, wearable devices with antennas integrated within temple arms of the smartglasses, and providing a battery management unit (BMU) in one or more spaces between a battery cell and an edge of a temple arm of a display device.

### BACKGROUND

With recent advances in technology, prevalence and proliferation of content creation and delivery has increased greatly in recent years. In particular, interactive content such as virtual reality (VR) content, augmented reality (AR) content, mixed reality (MR) content, and content within and associated with a real and/or virtual environment (e.g., a “metaverse”) has become appealing to consumers.

To facilitate delivery of this and other related content, service providers have endeavored to provide various forms wearable display devices. One such example may be a head-mounted device (HMD), such as wearable eyewear, wearable headset, or eyeglasses.

In some examples, to provide a display device or component that may trace a user's eye, one or more infrared (IR) light-emitting diodes (LEDs) may be mounted the display device or component. Conventionally, to place the one or more infrared (IR) light-emitting diodes (LEDs) properly, an operator may be required to line up and wrap (e.g., by hand) each light-emitting diode (LED) into its proper location. In some instances, this process may be cumbersome, time-consuming, and inefficient.

With recent advances in technology, prevalence and proliferation of content creation and delivery have increased greatly in recent years. In particular, interactive content such as virtual reality (VR) content, augmented reality (AR) content, mixed reality (MR) content, and content within and associated with a real and/or virtual environment (e.g., a “metaverse”) has become appealing to consumers.

Wearable devices, such as a wearable eyewear, wearable headsets, head-mountable devices, and smartglasses, have gained in popularity as forms of wearable systems. In some examples, such as when the wearable devices are eyeglasses or smartglasses, the wearable devices may include transparent or tinted lenses. In some examples, the wearable devices may employ imaging components to capture image content, such as photographs and videos. In some examples, such as when the wearable devices are head-mountable devices or smartglasses, the wearable devices may employ a first projector and a second projector to direct light associated with a first image and a second image, respectively, through one or more intermediary optical components at each respective lens, to generate “binocular” vision for viewing by a user.

Augmented reality (AR), virtual reality (VR), and mixed reality (MR) are modern technologies with potential for significant impact(s) on humanity. Various display devices, such as smart glasses, may provide augmented reality (AR), virtual reality (VR), and mixed reality (MR) experiences to a user.

In some instances, a device (e.g., a pair of wearable smart glasses) may include a number of components including, but not limited to, a camera, a projector, a viewing lens, a microphone, and a battery. It may be appreciated that these elements may be arranged in the display device in a manner to enable use by a consumer.

Specifically, aspects of a display device may be arranged such that a size, shape, and other physical specifications of components in the display device may provide maximum efficiency and comfort in use by a consumer. In some instances, this arrangement may be referred to as “form factor” for the device.

In some instances, one design aspect of a display device may conflict with another. For example, while a display device may benefit from a longer battery life, e.g., as provided by a larger battery unit, this may cause the body of the display device to become bulkier and/or heavier, and may cause discomfort to a wearing user.

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1 illustrates a block diagram of an artificial reality system environment including a near-eye display device, according to an example.

FIGS. 2A-2C illustrate various views of a near-eye display device in the form of a head-mounted display (HMD) device, according to examples.

FIG. 3 illustrates a perspective view and a top view of a near-eye display device in the form of a pair of glasses, according to an example.

FIG. 4 illustrates a schematic diagram of an optical system in a near-eye display system, according to an example.

FIG. 5 illustrates a diagram of a waveguide, according to an example.

FIG. 6 illustrates a diagram of a waveguide including an arrangement of volume Bragg gratings (VBGs), according to an example.

FIG. 7 illustrates a user's eye and a glint that may be projected toward and reflected from the user's eye, according to an example.

FIGS. 8A-8B illustrate a conventional arrangement of an eye tracking component having a plurality of infrared (IR) light-emitting diodes (LEDs), according to an example.

FIGS. 9A-9B illustrate eye tracking component arranged via implementation of laser direct structuring (LDS), according to examples.

FIGS. 10A-10B illustrate various aspects of an eye tracking component having an extension flexible printed circuit (FPC), according to an example.

FIG. 11 illustrates a block diagram of a system for implementing a conductive trace via laser direct structuring (LDS) and a light-emitting diode (LED) via surface-mount technology (SMT) on a carrier structure of a display device, according to an example.

FIG. 12 illustrates a method for implementing a conductive trace via laser direct structuring (LDS) and a light-emitting diode (LED) via surface-mount technology (SMT) on a carrier structure of a display device, according to an example.

FIG. 13 illustrates a perspective view of a wearable device having an integrated antenna, according to an example.

FIG. 14A illustrates a perspective view of the electronic components and the antenna housed in the hollow portion of the temple arm, according to an example.

FIG. 14B illustrates a rear perspective view of the features depicted in FIG. 14A, according to an example.

FIG. 14C illustrates an enlarged view of the antenna depicted in FIGS. 14A and 14B, according to an example.

FIG. 15A illustrates a perspective view of the electronic components and the antenna housed in the hollow portion of the temple arm as shown in FIG. 13, according to an example.

FIG. 15B illustrates a rear perspective view of the features depicted in FIG. 15A, according to an example.

FIG. 15C illustrates an enlarged view of the antenna depicted in FIGS. 15A and 15B, according to an example.

FIG. 16A illustrates a perspective view of the electronic components and the antenna housed in the hollow portion of the temple arm as shown in FIG. 13, according to an example.

FIG. 16B illustrates a rear perspective view of the features depicted in FIG. 16A, according to an example.

FIG. 16C illustrates an enlarged view of the antenna depicted in FIGS. 16A and 16B, according to an example.

FIG. 17 illustrates a perspective view of the electronic components and the antenna housed in the hollow portion of the temple arm as shown in FIG. 13, according to an example.

FIG. 18 illustrates a block diagram of an artificial reality system environment including a near-eye display device, according to an example.

FIGS. 19A-19C illustrate various views of a near-eye display device in the form of a head-mounted display (HMD) device, according to an example.

FIG. 20 is a perspective view of a near-eye display in the form of a pair of glasses, according to an example.

FIG. 21 illustrates a schematic diagram of an optical system in a near-eye display system, according to an example.

FIG. 22 illustrates components of a pair of wearable glasses, including a pair of temple arms and a pair of temple tips, according to an example.

FIG. 23A illustrates a pair of eyeglasses having a front tapering, according to an example.

FIG. 23B illustrates a pair of eyeglasses having a rear tapering, according to an example.

FIG. 24A illustrates a battery cell having a “conventional” design, according to an example.

FIG. 24B illustrates a metal-encased battery cell, according to an example.

FIG. 25 illustrates a display device arrangement having a tapered temple arm design including a metal-encased battery cell and a battery management unit (BMU), according to an example.

FIG. 26 illustrates a display device arrangement having a metal-encased battery cell and a battery management unit (BMU), according to an example.

FIG. 27 illustrates a display device arrangement having a metal-encased battery cell and a battery management unit (BMU), according to an example.

FIG. 28 illustrates a method for providing a battery management unit (BMU) in one or more spaces between a battery cell and an edge of a temple arm on smart glasses, according to an example.

### DETAILED DESCRIPTION

For simplicity and illustrative purposes, the present application is described by referring mainly to examples thereof. In the following description, numerous specific details are set forth in order to provide a thorough understanding of the present application. It will be readily apparent, however, that the present application may be practiced without limitation to these specific details. In other instances, some methods and structures readily understood by one of ordinary skill in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on. Augmented reality (AR), virtual reality (VR), and mixed reality (MR) are modern technologies with potential for significant impact(s) on humanity. Various digital displays, such as a smart glasses, may provide augmented reality (AR), virtual reality (VR), and mixed reality (MR) experiences to a user.

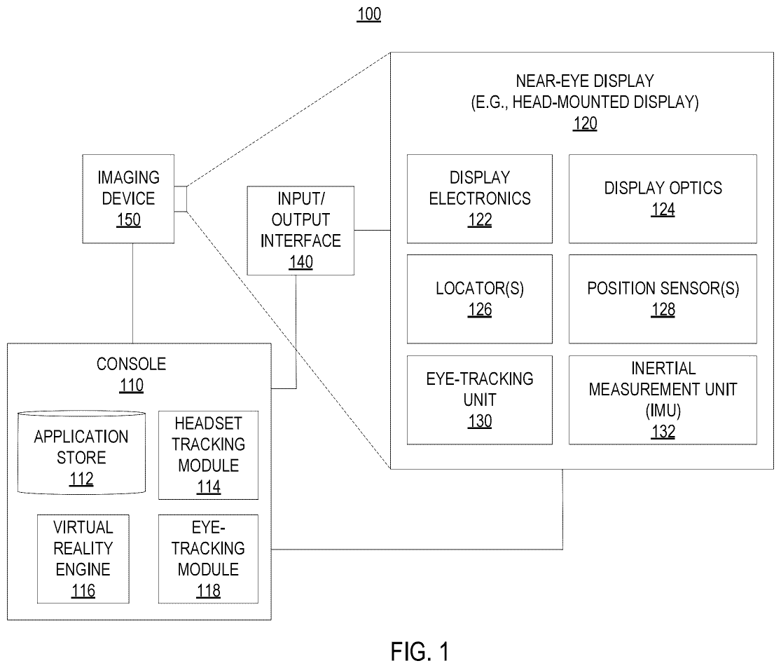

FIG. 1 illustrates a block diagram of an artificial reality system environment 100 including a near-eye display device, according to an example. As used herein, a “near-eye display device” may refer to a device (e.g., a display device) that may be in close proximity to a user's eye. As used herein, “artificial reality” may refer to aspects of, among other things, a “metaverse” or an environment of real and virtual elements and may include use of technologies associated with virtual reality (VR), augmented reality (AR), and/or mixed reality (MR). As used herein a “user” may refer to a user or wearer of a “near-eye display device.”

As shown in FIG. 1, the artificial reality system environment 100 may include a near-eye display device 120, an optional external imaging device 150, and an optional input/output interface 140, each of which may be coupled to a console 110. The console 110 may be optional in some instances as the functions of the console 110 may be integrated into the near-eye display device 120. In some examples, the near-eye display device 120 may be a head-mounted display (HMD) that presents content to a user.

In some instances, for a near-eye display device, it may generally be desirable to expand an eye box, reduce display haze, improve image quality (e.g., resolution and contrast), reduce physical size, increase power efficiency, and increase or expand field of view (FOV). As used herein, “field of view” (FOV) may refer to an angular range of an image as seen by a user, which is typically measured in degrees as observed by one eye (for a monocular head-mounted display (HMD)) or both eyes (for binocular head-mounted displays (HMDs)). Also, as used herein, an “eye box” may be a two-dimensional box that may be positioned in front of the user's eye from which a displayed image from an image source may be viewed.

In some examples, in a near-eye display device, light from a surrounding environment may traverse a “see-through” region of a waveguide display (e.g., a transparent substrate) to reach a user's eyes. For example, in a near-eye display device, light of projected images may be coupled into a transparent substrate of a waveguide, propagate within the waveguide, and be coupled or directed out of the waveguide at one or more locations to replicate exit pupils and expand the eye box.

In some examples, the near-eye display device 120 may include one or more rigid bodies, which may be rigidly or non-rigidly coupled to each other. In some examples, a rigid coupling between rigid bodies may cause the coupled rigid bodies to act as a single rigid entity, while in other examples, a non-rigid coupling between rigid bodies may allow the rigid bodies to move relative to each other.

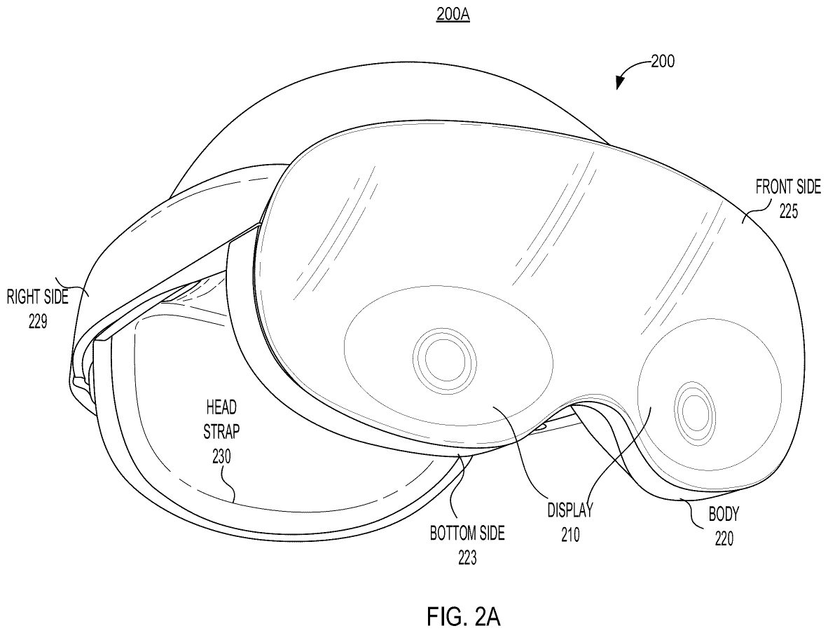

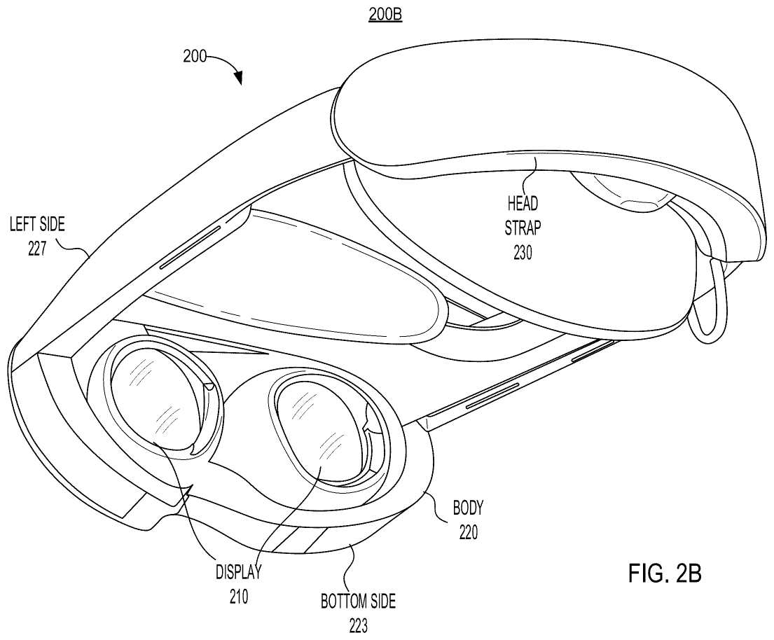

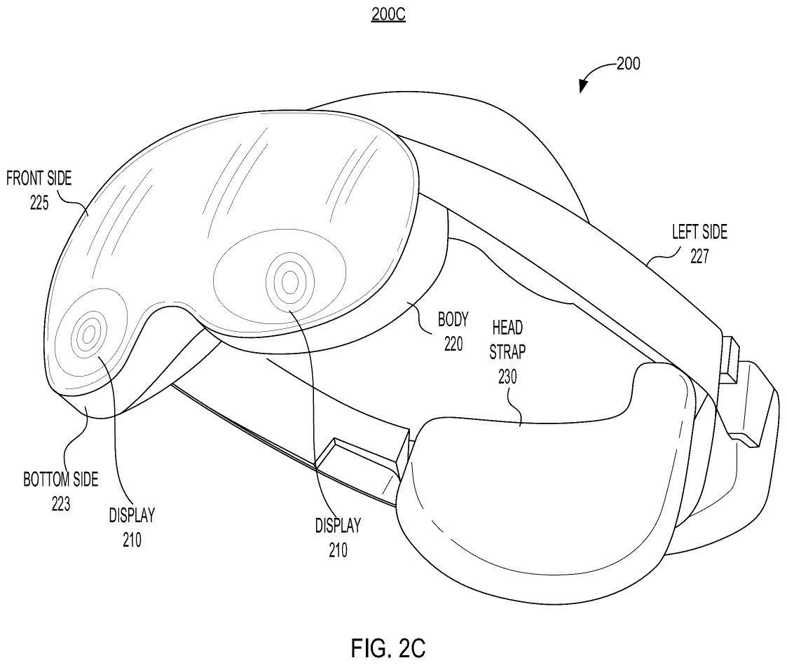

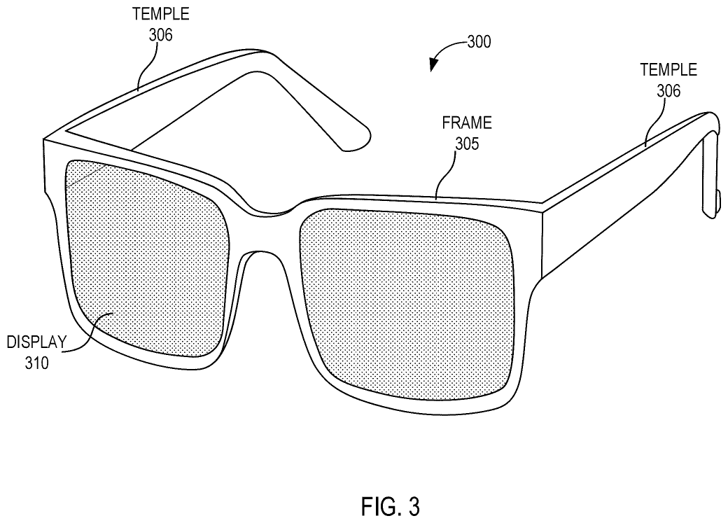

In some examples, the near-eye display device 120 may be implemented in any suitable form-factor, including a head-mounted display (HMD), a pair of glasses, or other similar wearable eyewear or device. Examples of the near-eye display device 120 are further described below with respect to FIGS. 2 and 3. Additionally, in some examples, the functionality described herein may be used in a head-mounted display (HMD) or headset that may combine images of an environment external to the near-eye display device 120 and artificial reality content (e.g., computer-generated images). Therefore, in some examples, the near-eye display device 120 may augment images of a physical, real-world environment external to the near-eye display device 120 with generated and/or overlaid digital content (e.g., images, video, sound, etc.) to present an augmented reality to a user.

In some examples, the near-eye display device 120 may include any number of display electronics 122, display optics 124, and an eye tracking unit 130. In some examples, the near-eye display device 120 may also include one or more locators 126, one or more position sensors 128, and an inertial measurement unit (IMU) 132. In some examples, the near-eye display device 120 may omit any of the eye tracking unit 130, the one or more locators 126, the one or more position sensors 128, and the inertial measurement unit (IMU) 132, or may include additional elements.

In some examples, the display electronics 122 may display or facilitate the display of images to the user according to data received from, for example, the optional console 110. In some examples, the display electronics 122 may include one or more display panels. In some examples, the display electronics 122 may include any number of pixels to emit light of a predominant color such as red, green, blue, white, or yellow. In some examples, the display electronics 122 may display a three-dimensional (3D) image, e.g., using stereoscopic effects produced by two-dimensional panels, to create a subjective perception of image depth.

In some examples, the near-eye display device 120 may include a projector (not shown), which may form an image in angular domain for direct observation by a viewer's eye through a pupil. The projector may employ a controllable light source (e.g., a laser source) and a micro-electromechanical system (MEMS) beam scanner to create a light field from, for example, a collimated light beam. In some examples, the same projector or a different projector may be used to project a fringe pattern on the eye, which may be captured by a camera and analyzed (e.g., by the eye tracking unit 130) to determine a position of the eye (the pupil), a gaze, etc.

In some examples, the display optics 124 may display image content optically (e.g., using optical waveguides and/or couplers) or magnify image light received from the display electronics 122, correct optical errors associated with the image light, and/or present the corrected image light to a user of the near-eye display device 120. In some examples, the display optics 124 may include a single optical element or any number of combinations of various optical elements as well as mechanical couplings to maintain relative spacing and orientation of the optical elements in the combination. In some examples, one or more optical elements in the display optics 124 may have an optical coating, such as an anti-reflective coating, a reflective coating, a filtering coating, and/or a combination of different optical coatings.

In some examples, the display optics 124 may also be designed to correct one or more types of optical errors, such as two-dimensional optical errors, three-dimensional optical errors, or any combination thereof. Examples of two-dimensional errors may include barrel distortion, pincushion distortion, longitudinal chromatic aberration, and/or transverse chromatic aberration. Examples of three-dimensional errors may include spherical aberration, chromatic aberration field curvature, and astigmatism.

In some examples, the one or more locators 126 may be objects located in specific positions relative to one another and relative to a reference point on the near-eye display device 120. In some examples, the optional console 110 may identify the one or more locators 126 in images captured by the optional external imaging device 150 to determine the artificial reality headset's position, orientation, or both. The one or more locators 126 may each be a light-emitting diode (LED), a corner cube reflector, a reflective marker, a type of light source that contrasts with an environment in which the near-eye display device 120 operates, or any combination thereof.

In some examples, the external imaging device 150 may include one or more cameras, one or more video cameras, any other device capable of capturing images including the one or more locators 126, or any combination thereof. The optional external imaging device 150 may be configured to detect light emitted or reflected from the one or more locators 126 in a field of view of the optional external imaging device 150.

In some examples, the one or more position sensors 128 may generate one or more measurement signals in response to motion of the near-eye display device 120. Examples of the one or more position sensors 128 may include any number of accelerometers, gyroscopes, magnetometers, and/or other motion-detecting or error-correcting sensors, or any combination thereof.

In some examples, the inertial measurement unit (IMU) 132 may be an electronic device that generates fast calibration data based on measurement signals received from the one or more position sensors 128. The one or more position sensors 128 may be located external to the inertial measurement unit (IMU) 132, internal to the inertial measurement unit (IMU) 132, or any combination thereof. Based on the one or more measurement signals from the one or more position sensors 128, the inertial measurement unit (IMU) 132 may generate fast calibration data indicating an estimated position of the near-eye display device 120 that may be relative to an initial position of the near-eye display device 120. For example, the inertial measurement unit (IMU) 132 may integrate measurement signals received from accelerometers over time to estimate a velocity vector and integrate the velocity vector over time to determine an estimated position of a reference point on the near-eye display device 120. Alternatively, the inertial measurement unit (IMU) 132 may provide the sampled measurement signals to the optional console 110, which may determine the fast calibration data.

The eye tracking unit 130 may include one or more eye tracking components. As used herein, “eye tracking” may refer to determining an eye's position or relative position, including orientation, location, gaze of a user's eye, and opening and closing of the user's eye as well. In some examples, an eye tracking component may include an imaging system that captures one or more images of an eye and may optionally include a light emitter, which may generate infrared (IR) light (e.g., a fringe pattern) that is directed to an eye such that light reflected by the eye may be captured by the imaging system (e.g., a camera). In other examples, the eye tracking unit 130 may capture reflected radio waves emitted by a miniature radar unit. These data associated with the eye may be used to determine or predict eye position, orientation, movement, location, and/or gaze.

In some examples, the near-eye display device 120 may use the orientation of the eye to introduce depth cues (e.g., blur image outside of the user's main line of sight), collect heuristics on the user interaction in the virtual reality (VR) media (e.g., time spent on any particular subject, object, or frame as a function of exposed stimuli), some other functions that are based in part on the orientation of at least one of the user's eyes, or any combination thereof. In some examples, because the orientation may be determined for both eyes of the user, the eye tracking unit 130 may be able to determine where the user is looking or predict any user patterns, etc.

In some examples, the input/output interface 140 may be a device that allows a user to send action requests to the optional console 110. As used herein, an “action request” may be a request to perform a particular action. For example, an action request may be to start or to end an application or to perform a particular action within the application. The input/output interface 140 may include one or more input devices. Example input devices may include a keyboard, a mouse, a game controller, a glove, a button, a touch screen, or any other suitable device for receiving action requests and communicating the received action requests to the optional console 110. In some examples, an action request received by the input/output interface 140 may be communicated to the optional console 110, which may perform an action corresponding to the requested action.

In some examples, the optional console 110 may provide content to the near-eye display device 120 for presentation to the user in accordance with information received from at least one of external imaging device 150, the near-eye display device 120, and the input/output interface 140. For example, in the example shown in FIG. 1, the optional console 110 may include an application store 112, a headset tracking module 114, a virtual reality engine 116, and an eye tracking module 118. Some examples of the optional console 110 may include different or additional modules than those described in conjunction with FIG. 1. Functions further described below may be distributed among components of the optional console 110 in a different manner than is described here.

In some examples, the optional console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In some examples, the modules of the optional console 110 described in conjunction with FIG. 1 may be encoded as instructions in the non-transitory computer-readable storage medium that, when executed by the processor, cause the processor to perform the functions further described below. It should be appreciated that the optional console 110 may or may not be needed or the optional console 110 may be integrated with or separate from the near-eye display device 120.

In some examples, the application store 112 may store one or more applications for execution by the optional console 110. An application may include a group of instructions that, when executed by a processor, generates content for presentation to the user. Examples of the applications may include gaming applications, conferencing applications, video playback application, or other suitable applications.

In some examples, the headset tracking module 114 may track movements of the near-eye display device 120 using slow calibration information from the external imaging device 150. For example, the headset tracking module 114 may determine positions of a reference point of the near-eye display device 120 using observed locators from the slow calibration information and a model of the near-eye display device 120. Additionally, in some examples, the headset tracking module 114 may use portions of the fast calibration information, the slow calibration information, or any combination thereof, to predict a future location of the near-eye display device 120. In some examples, the headset tracking module 114 may provide the estimated or predicted future position of the near-eye display device 120 to the virtual reality engine 116.

In some examples, the virtual reality engine 116 may execute applications within the artificial reality system environment 100 and receive position information of the near-eye display device 120, acceleration information of the near-eye display device 120, velocity information of the near-eye display device 120, predicted future positions of the near-eye display device 120, or any combination thereof from the headset tracking module 114. In some examples, the virtual reality engine 116 may also receive estimated eye position and orientation information from the eye tracking module 118. Based on the received information, the virtual reality engine 116 may determine content to provide to the near-eye display device 120 for presentation to the user.

In some examples, the eye tracking module 118, which may be implemented as a processor, may receive eye tracking data from the eye tracking unit 130 and determine the position of the user's eye based on the eye tracking data. In some examples, the position of the eye may include an eye's orientation, location, or both relative to the near-eye display device 120 or any element thereof. So, in these examples, because the eye's axes of rotation change as a function of the eye's location in its socket, determining the eye's location in its socket may allow the eye tracking module 118 to more accurately determine the eye's orientation.

In some examples, a location of a projector of a display system may be adjusted to enable any number of design modifications. For example, in some instances, a projector may be located in front of a viewer's eye (e.g., “front-mounted” placement). In a front-mounted placement, in some examples, a projector of a display system may be located away from a user's eyes (e.g., “world-side”). In some examples, a head-mounted display (HMD) device may utilize a front-mounted placement to propagate light towards a user's eye(s) to project an image.

FIGS. 2A-2C illustrate various views of a near-eye display device in the form of a head-mounted display (HMD) device 200, according to examples. In some examples, the head-mounted device (HMD) device 200 may be a part of a virtual reality (VR) system, an augmented reality (AR) system, a mixed reality (MR) system, another system that uses displays or wearables, or any combination thereof. As shown in diagram 200A of FIG. 2A, the head-mounted display (HMD) device 200 may include a body 220 and a head strap 230. The front perspective view of the head-mounted display (HMD) device 200 further shows a bottom side 223, a front side 225, and a right side 229 of the body 220. In some examples, the head strap 230 may have an adjustable or extendible length. In particular, in some examples, there may be a sufficient space between the body 220 and the head strap 230 of the head-mounted display (HMD) device 200 for allowing a user to mount the head-mounted display (HMD) device 200 onto the user's head. For example, the length of the head strap 230 may be adjustable to accommodate a range of user head sizes. In some examples, the head-mounted display (HMD) device 200 may include additional, fewer, and/or different components such as a display 210 to present a wearer augmented reality (AR)/virtual reality (VR) content and a camera to capture images or videos of the wearer's environment.

As shown in the bottom perspective view of diagram 200B of FIG. 2B, the display 210 may include one or more display assemblies and present, to a user (wearer), media or other digital content including virtual and/or augmented views of a physical, real-world environment with computer-generated elements. Examples of the media or digital content presented by the head-mounted display (HMD) device 200 may include images (e.g., two-dimensional (2D) or three-dimensional (3D) images), videos (e.g., 2D or 3D videos), audio, or any combination thereof. In some examples, the user may interact with the presented images or videos through eye tracking sensors enclosed in the body 220 of the head-mounted display (HMD) device 200. The eye tracking sensors may also be used to adjust and improve quality of the presented content.

In some examples, the head-mounted display (HMD) device 200 may include a fringe-projection profilometry (FPP) projector and the camera or the eye tracking sensors may include a dual readout sensor. The projector may transmit a frequency signal pattern and a zero-frequency signal pattern onto an object's (e.g., eye in case of eye tracking) surface. The projector may also transmit two periodic phase-shifted frequency signal patterns onto the object's surface, where the two phase-shifted frequency signal patterns may be phase-shifted by 180 degrees. The dual readout sensor may capture reflections of both transmitted patterns (frequency and zero frequency or phase-shifted frequency signal patterns), and a direct component (DC) signal may be removed through subtraction or cancellation. In both examples, the derived signal may be used to generate a wrapped phase map through Fourier transform profilometry (FTP). The resulting wrapped phase map may be unwrapped, for example, using a depth-calibrated unwrapped phase map. A three-dimensional reconstruction of the object's surface may be generated by converting phase from the unwrapped phase map to three-dimensional coordinates.

In some examples, the head-mounted display (HMD) device 200 may include various sensors (not shown), such as depth sensors, motion sensors, position sensors, and/or eye tracking sensors. Some of these sensors may use any number of structured or unstructured light patterns for sensing purposes. In some examples, the head-mounted display (HMD) device 200 may include an input/output interface for communicating with a console communicatively coupled to the head-mounted display (HMD) device 200 through wired or wireless means. In some examples, the head-mounted display (HMD) device 200 may include a virtual reality engine (not shown) that may execute applications within the head-mounted display (HMD) device 200 and receive depth information, position information, acceleration information, velocity information, predicted future positions, or any combination thereof of the head-mounted display (HMD) device 200 from the various sensors.

In some examples, the information received by the virtual reality engine may be used for producing a signal (e.g., display instructions) to the display 210. In some examples, the head-mounted display (HMD) device 200 may include locators (not shown), which may be located in fixed positions on the body 220 of the head-mounted display (HMD) device 200 relative to one another and relative to a reference point. Each of the locators may emit light that is detectable by an external imaging device. This may be useful for the purposes of head tracking or other movement/orientation. It should be appreciated that other elements or components may also be used in addition or in lieu of such locators.

FIG. 3 is a perspective view of a near-eye display device 300 in the form of a pair of glasses (or other similar eyewear), according to an example. In some examples, the near-eye display device 300 may be a specific example of near-eye display device 120 of FIG. 1 and may be configured to operate as a virtual reality display, an augmented reality (AR) display, and/or a mixed reality (MR) display.

In some examples, the near-eye display device 300 may include a frame 305 and a display 310. In some examples, the display 310 may be configured to present media or other content to a user. In some examples, the display 310 may include display electronics and/or display optics, similar to components described with respect to FIGS. 1-2. For example, as described above with respect to the near-eye display device 120 of FIG. 1, the display 310 may include a liquid crystal display (LCD) display panel, a light-emitting diode (LED) display panel, or an optical display panel (e.g., a waveguide display assembly). In some examples, the display 310 may also include any number of optical components, such as waveguides, gratings, lenses, mirrors, etc. In other examples, the display 210 may include a projector, or in place of the display 310 the near-eye display device 300 may include a projector.

In some examples, the near-eye display device 300 may further include various sensors on or within a frame 305. In some examples, the various sensors may include any number of depth sensors, motion sensors, position sensors, inertial sensors, and/or ambient light sensors, as shown. In some examples, the various sensors may include any number of image sensors configured to generate image data representing different fields of views in one or more different directions. In some examples, the various sensors may be used as input devices to control or influence the displayed content of the near-eye display device, and/or to provide an interactive virtual reality (VR), augmented reality (AR), and/or mixed reality (MR) experience to a user of the near-eye display device 300. In some examples, the various sensors may also be used for stereoscopic imaging or other similar applications.

In some examples, the near-eye display device 300 may further include one or more illuminators to project light into a physical environment. The projected light may be associated with different frequency bands (e.g., visible light, infra-red light, ultra-violet light, etc.), and may serve various purposes. In some examples, the one or more illuminator(s) may be used as locators, such as the one or more locators 126 described above with respect to FIGS. 1-2.

In some examples, the near-eye display device 300 may also include a camera or other image capture unit. The camera, for instance, may capture images of the physical environment in the field of view. In some instances, the captured images may be processed, for example, by a virtual reality engine (e.g., the virtual reality engine 116 of FIG. 1) to add virtual objects to the captured images or modify physical objects in the captured images, and the processed images may be displayed to the user by the display 310 for augmented reality (AR) and/or mixed reality (MR) applications. The near-eye display device 300 may also include an eye tracking camera.

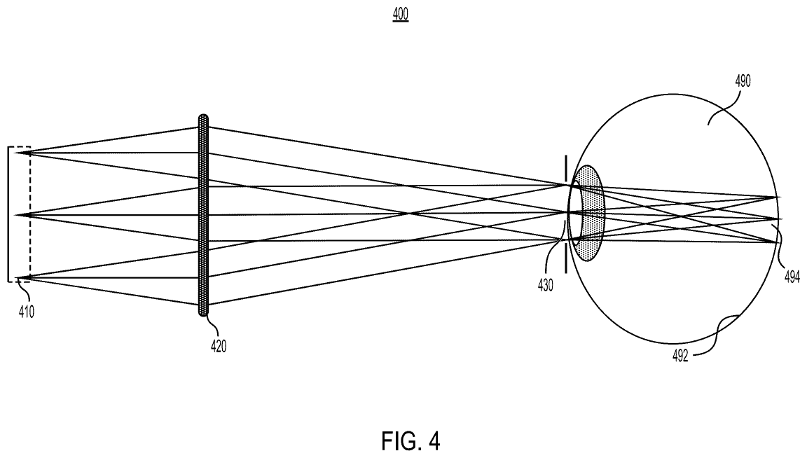

FIG. 4 illustrates a schematic diagram of an optical system 400 in a near-eye display system, according to an example. In some examples, the optical system 400 may include an image source 410 and any number of projector optics 420 (which may include waveguides having gratings as discussed herein). In the example shown in FIG. 4, the image source 410 may be positioned in front of the projector optics 420 and may project light toward the projector optics 420. In some examples, the image source 410 may be located outside of the field of view (FOV) of a user's eye 490. In this case, the projector optics 420 may include one or more reflectors, refractors, or directional couplers that may deflect light from the image source 410 that is outside of the field of view (FOV) of the user's eye 490 to make the image source 410 appear to be in front of the user's eye 490. Light from an area (e.g., a pixel or a light emitting device) on the image source 410 may be collimated and directed to an exit pupil 430 by the projector optics 420. Thus, objects at different spatial locations on the image source 410 may appear to be objects far away from the user's eye 490 in different viewing angles (e.g., fields of view (FOV)). The collimated light from different viewing angles may then be focused by the lens of the user's eye 490 onto different locations on retina 492 of the user's eye 490. For example, at least some portions of the light may be focused on a fovea 494 on the retina 492. Collimated light rays from an area on the image source 410 and incident on the user's eye 490 from a same direction may be focused onto a same location on the retina 492. As such, a single image of the image source 410 may be formed on the retina 492.

In some instances, a user experience of using an artificial reality system may depend on several characteristics of the optical system, including field of view (FOV), image quality (e.g., angular resolution), size of the eyebox (to accommodate for eye and head movements), and brightness of the light (or contrast) within the eyebox. Also, in some examples, to create a fully immersive visual environment, a large field of view (FOV) may be desirable because a large field of view (FOV) (e.g., greater than about) 60° may provide a sense of “being in” an image, rather than merely viewing the image. In some instances, smaller fields of view may also preclude some important visual information. For example, a head-mounted display (HMD) system with a small field of view (FOV) may use a gesture interface, but users may not readily see their hands in the small field of view (FOV) to be sure that they are using the correct motions or movements. On the other hand, wider fields of view may require larger displays or optical systems, which may influence the size, weight, cost, and/or comfort of the head-mounted display (HMD) itself.

In some examples, a waveguide may be utilized to couple light into and/or out of a display system. In particular, in some examples and as described further below, light of projected images may be coupled into or out of the waveguide using any number of reflective or diffractive optical elements, such as gratings. For example, as described further below, one or more volume Bragg gratings (VBGs) may be utilized in a waveguide-based, back-mounted display system (e.g., a pair of glasses or similar eyewear).

In some examples, one or more volume Bragg gratings (VBGs) (or two portions of a same grating) may be used to diffract display light from a projector to a user's eye. Furthermore, in some examples, the one or more volume Bragg gratings (VBGs) may also help compensate for any dispersion of display light caused by each other to reduce the overall dispersion in a waveguide-based display system.

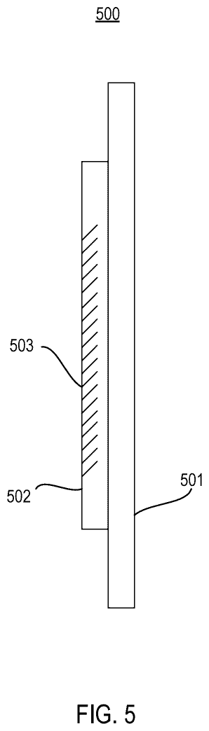

FIG. 5 illustrates a diagram of a waveguide configuration 500, according to an example. In some examples, the waveguide configuration 500 may include a plurality of layers, such as at least one substrate 501 and at least one photopolymer layer 502. In some examples, the substrate 501 may be a comprised of a polymer or glass material. In some examples, the photopolymer layer 502 may be transparent or “see-through”, and may include any number of photosensitive materials (e.g., a photo-thermo-refractive glass) or other similar material.

In some examples, at least one substrate 501 and at least one photopolymer layer 502 may be optically bonded (e.g., glued on top of each other) to form the waveguide configuration 500. In some examples, the substrate 501 may have a thickness of anywhere between around 0.1-1.0 millimeters (mm) or other thickness range. In some examples, the photopolymer layer 502 may be a film layer having a thickness of anywhere between about 50-500 micrometers (μm) or other range.

In some examples, one or more volume Bragg gratings (VBGs) may be provided in (or exposed into) the photopolymer layer 502. That is, in some examples, one or more (e.g., from ten to hundreds) volume Bragg gratings may be exposed by generating an interference pattern 503 into the photopolymer layer 502. In some examples, the interference pattern 503 may be generated by superimposing two lasers to create a spatial modulation (e.g., an alteration of an existing refractive index) that may generate the interference pattern 503 in and/or throughout the photopolymer layer 502. In some examples, the interference pattern 503 may be a sinusoidal pattern. Also, in some examples, the interference pattern 503 may be made permanent via a chemical, optical, mechanical, or other similar process.

By exposing the interference pattern 503 into the photopolymer layer 502, for example, the refractive index of the photopolymer layer 502 may be altered and a volume Bragg grating may be provided in the photopolymer layer 502. Indeed, in some examples, a plurality of volume Bragg gratings or one or more sets of volume Bragg gratings may be exposed in the photopolymer layer 502. It should be appreciated that this technique may be referred to as “multiplexing.” It should also be appreciated that other various techniques to provide a volume Bragg grating (VBG) in the photopolymer layer 502 may also be provided.

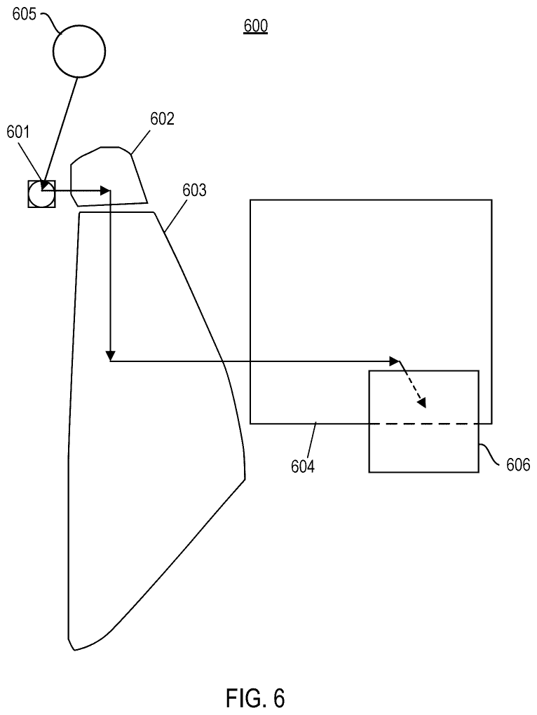

FIG. 6 illustrates a diagram of a waveguide configuration 600 including an arrangement of volume Bragg gratings (VBGs), according to an example. In some examples, the waveguide configuration 600 may be used a display system, similar to the near-eye display system 300 of FIG. 3. The waveguide configuration 600, as shown, may include an input volume Bragg grating (VBG) 601 (“input grating” or “IG”, “inbound grating”, or “in-coupling grating”), a first middle volume Bragg grating (VBG) 602 (“first middle grating” or “MG1”), a second middle volume Bragg grating (VBG) 603 (“second middle grating” or “MG2”), and an output volume Bragg grating (VBG) 604 (“output grating” or “OG”, “outbound grating”, or “out-coupling grating”). It should be appreciated that, as used herein and in some instances, the terms “grating” and “gratings” may be used interchangeably, in that “grating” may include an arrangement of a plurality of gratings or grating structures.

In some examples, a projector 605 of the display system may transmit display light (indicated by an arrow) to the arrangement of volume Bragg gratings (VBGs) 601-604, starting with the input volume Bragg grating (VBG) 601 (which receives the display light from the projector), then through the first middle volume Bragg grating (VBG) 602 and the second middle volume Bragg grating (VBG) 603, and then to the output volume Bragg grating (VBG) 604 which directs the display light to an eyebox or a user's eye 606.

As discussed above, the waveguide configuration 600 may include any number of volume Bragg gratings (VBGs) that may be exposed into a “see-through” photopolymer material, such as glass or plastic. In some examples and as discussed above, at least one of the arrangement of volume Bragg gratings (VBGs) 601-604 may be patterned (e.g., using sinusoidal patterning) into and/or on a surface of the photopolymer material. In this way, the waveguide configuration 600 may be relatively transparent so that a user may see through to the other side. At the same time, the waveguide configuration 600, with its various arrangements of volume Bragg gratings (VBGs) 601-604 may (among other things) receive the propagated display light from the projector and exit the propagated display light in front of a user's eyes for viewing. In this way any number of augmented reality (AR) and/or mixed reality (MR) environments may be provided to and experienced by the user. In addition, in some examples, the arrangement of volume Bragg gratings (VBGs) 601-604 may be implemented to “expand” (e.g., horizontally and/or vertically) a region in space to be viewed so that a user may view a displayed image regardless of where a pupil of a user's eye may be. As such, in some examples, by expanding this viewing region, the arrangement of volume Bragg gratings (VBGs) 601-604 may ensure that a user may move their eye in various directions and still view the displayed image.

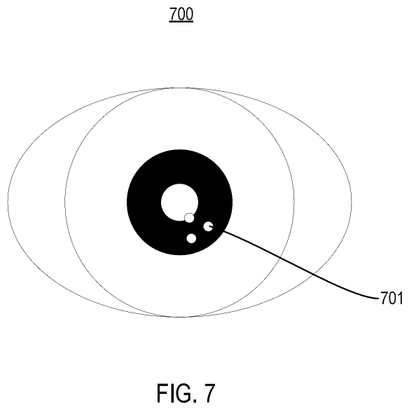

In some examples, to determine where or what a user may be viewing, a display system as described herein may utilize a light-emitting diode (LED) (e.g., an infrared (IR)) light-emitting diode (LED)) to aid a camera device or component to locate a location of a pupil. In some instances, this may be referred as “tracing.” In some examples, the light-emitting diode (LED) shape (e.g., a dot) reflected off of the user's eye may be referred to as a “glint.” FIG. 7 illustrates a user's eye 700 and a glint 701 that may be reflected from the user's eye 700.

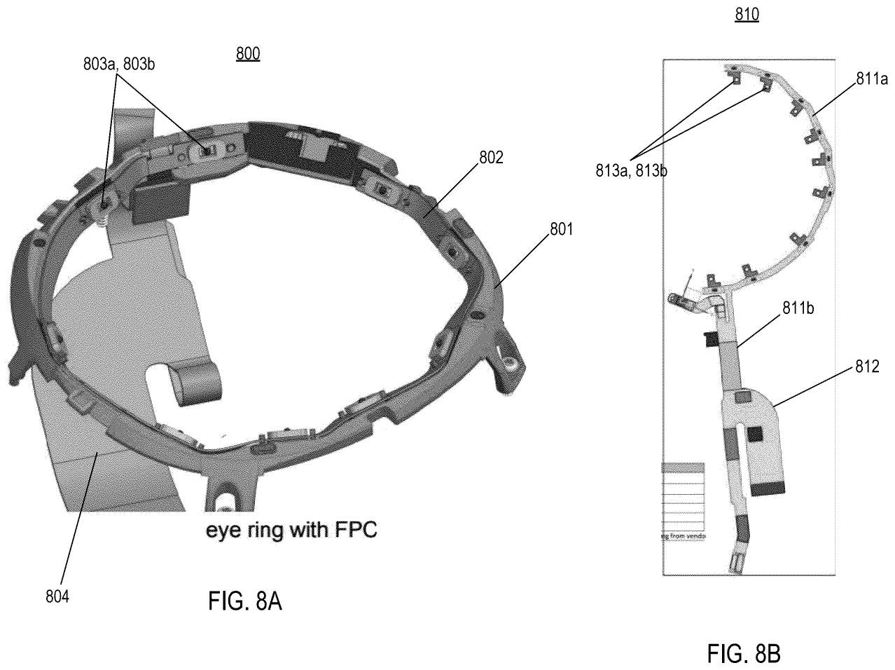

In some examples, an infrared (IR) light-emitting diode (LED) may be located on a display component so that the infrared (IR) light-emitting diode (LED) may be directed toward a user's eye and may trace the user's eye (or pupil). FIGS. 8A-8B illustrate a conventional arrangement of a display component having a plurality of infrared (IR) light-emitting diodes (LEDs), according to an example. FIG. 8A illustrates a display component 800 that includes a carrier (e.g., comprised of a plastic material) 801 that may house a “ring” portion of a flexible printed circuit (FPC) 802, wherein the ring portion of the flexible printed circuit (FPC) 802 may comprise a plurality of infrared (IR) light-emitting diodes (LEDs) 803a-803b. As used herein, a “carrier” may include any housing component that may be utilized to house at least one of a conductive trace and a light-emitting diode (LED). In some examples, the ring portion of the flexible printed circuit (FPC) 802 may be coupled to a controller portion of the flexible printed circuit (FPC) 804, which may control aspects of operation of the display component 800.

As discussed above, in some examples, the plurality of infrared (IR) light-emitting diodes (LEDs) 803a-803b may each be located to track a user's eye. Specifically, in some examples, as the display component 800 may track a user's eye, the display component 800 utilize a (known) location of each of the plurality of infrared (IR) light-emitting diodes (LEDs) 803a-803b, and may illuminate the plurality of infrared (IR) light-emitting diodes (LEDs) 803a-803b to track the user's eye and to determine what the user may be viewing (e.g., which portion of a display the user may be viewing).

In some examples, to provide a display component that may trace a user's eye, a plurality of infrared (IR) light-emitting diodes (LEDs) (e.g., the plurality of infrared (IR) light-emitting diodes (LEDs) 803a-803b) may be mounted onto a flexible printed circuit (FPC) (e.g., the “ring” portion of a flexible printed circuit (FPC) 802). Specifically, in some examples, a surface-mount technology (SMT) may be utilized to couple (e.g., solder) each the one or more infrared (IR) light-emitting diodes (LEDs) to the flexible printed circuit (FPC) at particular (“soldering”) locations.

Moreover, upon mounting the one or more infrared (IR) light-emitting diodes (LEDs) to the flexible printed circuit (FPC), the flexible printed circuit (FPC) (e.g., the ring portion of the flexible printed circuit (FPC) 802) may be mounted onto a carrier (e.g., the carrier 801). In some examples, the carrier may be comprised of a plastic material.

FIG. 8B illustrates an eye tracking component 810 that includes a “ring” portion of a flexible printed circuit (FPC) 811a, wherein the ring portion of the flexible printed circuit (FPC) 811a may comprise a plurality of infrared (IR) light-emitting diodes (LEDs) 813a-813b. In some examples, the ring portion of the flexible printed circuit (FPC) 811a may be coupled to an extension flexible printed circuit (FPC) 811b, which may further be coupled to a controller flexible printed circuit (FPC) 812. As used herein, an “extension flexible printed circuit” may include any flexible printed circuit (FPC) that may be communicatively coupled to a trace located on a carrier. Also, as used herein, a “controller flexible printed circuit” may include any flexible printed circuit (FPC) that may be communicatively coupled to provide operation of an extension flexible printed circuit (FPC). In some examples, the extension flexible printed circuit (FPC) 811b may and the controller flexible printed circuit (FPC) 812 may operate aspects of the eye tracking component 810 (e.g., operation of at least one of the light-emitting diodes 813a-813b).

It may be appreciated that, in some instances, in order to properly place the one or more infrared (IR) light-emitting diodes (LEDs) on to the flexible printed circuit (FPC) and to properly place the flexible printed circuit (FPC) on to the carrier, an operator may be required to line up and wrap (e.g., by hand) each light-emitting diodes (LED) of the one or more infrared (IR) light-emitting diodes (LEDs) with respect to its proper location. Specifically, in some examples, an operator may be required to (e.g., again, by hand) utilize one or more guide pins to place each light-emitting diodes (LED) into its appropriate location.

It may be apparent that this process, in some instances, may be cumbersome, time-consuming, and inefficient. Furthermore, it may be appreciated that other related issues may arise as well. For example, in some instances, a cost of a unit printed flexible circuit (FPC), such as a flexible printed circuit (FPC) that may be wrapped along an inside of a carrier (e.g., the “ring” portion of a flexible printed circuit (FPC) 802), may be unduly expensive.

Systems and methods described herein may provide implementing of a conductive trace via laser direct structuring (LDS) and a light-emitting diode (LED) via surface-mount technology (SMT) on a carrier structure of a display device. In some examples, the systems and methods may include devices and components having at least one light-emitting diode (LED) (e.g., an infrared (IR) light-emitting diode (LED)) that may be electrically coupled via one or more conductive traces. In some examples, the light-emitting diodes (LEDs) may be mounted directly on a carrier, wherein the light-emitting diodes (LEDs) may be electrically and operably coupled to with a flexible printed circuit (FPC). In some examples, and as will be illustrated below, the flexible printed circuit (FPC) may not be wrapped along an inside of carrier (e.g., a circular carrier), but instead may extend away from the carrier in a relatively limited manner.

In some examples, a light-emitting diode (LED) (e.g., an infrared (IR) light-emitting diode (LED)) and/or a conductive trace may be provided on a carrier via laser direct structuring (LDS). In some examples, laser direct structuring (LDS) may include, among other things, a manufacturing process in which the light-emitting diode (LED) and/or a conductive trace may be implemented directly on an injection-molded plastic (e.g., a plastic carrier).

It may be appreciated that implementing surface-mount technology and laser direct structuring (LDS) as described herein, accuracy of eye tracking may be increased. Specifically, in some examples, because conventional methods may (typically) utilize one or more guide pins on a plastic carrier to locate a flexible printed circuit (FPC), the conventional methods may not be as accurate as surface-mount technology (SMT) light-emitting diodes (LEDs) that may be directly placed on the plastic carrier. That is, in a conventional arrangement, a flexible printed circuit (FPC) may employ one or more locating holes that may have to be larger than (corresponding) locating pins, and may require locating holes located on a flexible printed circuit (FPC) to have some positional tolerance relative to the light-emitting diodes (LEDs). Instead, by implementing surface-mount technology (SMT) to place one or more light-emitting diodes (LEDs) directly on the plastic carrier, the systems and methods described herein may reduce associated tolerances and thereby increase precision of positioning of the light-emitting diodes (LEDs).

In some examples, systems and methods described herein may include a carrier including a conductive trace, wherein the conductive trace is printed onto the carrier; a light-emitting diode (LED) mounted onto the carrier; and a flexible printed circuit (FPC) attached to the carrier, wherein the light-emitting diode (LED) is communicatively coupled to the flexible printed circuit (FPC) via the conductive trace. In some examples, the light-emitting diode (LED) is an infrared (IR) light-emitting diode (LED), the conductive trace is printed via laser direct structuring (LDS), and the light-emitting diode (LED) is mounted via surface-mount technology (SMT). Also, in some examples, the light-emitting diode (LED) is mounted utilizing a slanted profile, the light-emitting diode (LED) is mounted utilizing a flat profile, and the flexible printed circuit (FPC) is approximately twenty-five (25) to thirty (30) millimeters in length.

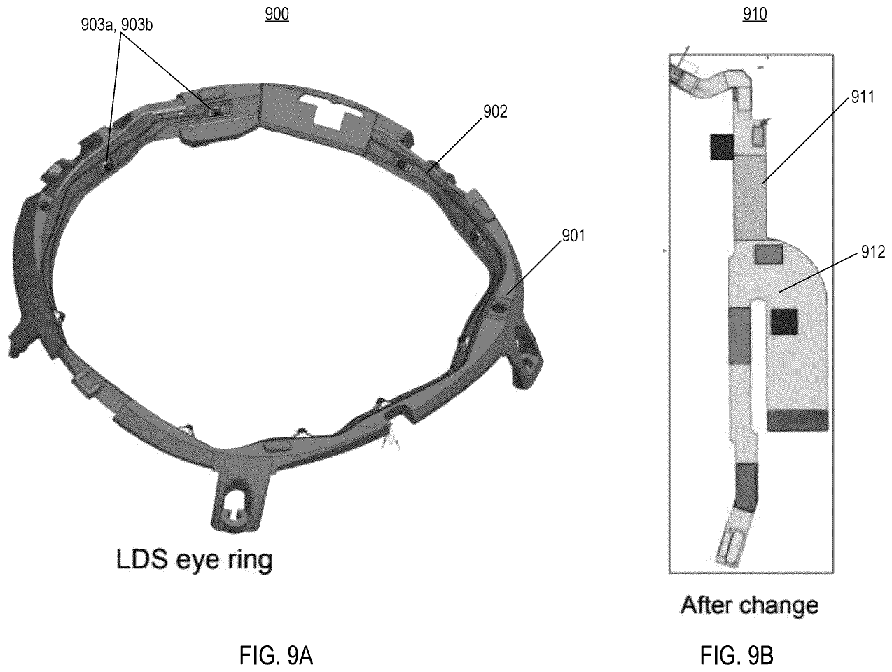

FIGS. 9A-9B illustrate display components arranged via implementation of laser direct structuring (LDS), according to an example. FIG. 9A illustrates an eye tracking component 900 implementing laser direct structuring (LDS) to provide at least one light-emitting diode (LED) and operably coupled conductive traces, according to an example. In some examples, laser direct structuring (LDS) may be utilized to create conductive traces 902 on carrier 901. Also, in some examples, surface-mount technology (SMT) may be utilized to couple infrared (IR) light-emitting diodes (LEDs) 903a-903b directly onto the carrier 901.

FIG. 9B illustrates an arrangement of an eye tracking component 910 that may include an extension flexible printed circuit (FPC) 911 and a controller flexible printed circuit (FPC) 912, according to an example. In some examples, the extension flexible printed circuit (FPC) 911 may be utilized to couple to conductive traces (e.g., the conductive traces 902) that may be printed on a carrier (e.g., the carrier 901). In addition, in some examples, the extension flexible printed circuit (FPC) 911 may be coupled to the controller flexible printed circuit (FPC) 912, which may be used to operate aspects of the eye tracking component 910 (e.g., operation of at least one of the light-emitting diodes 903a-903b).

In some examples, where at least one light-emitting diode (LED) (e.g., the infrared (IR) light-emitting diodes (LEDs) 903a-903b) may be provided on a carrier (e.g., the carrier 901) via surface-mount technology (SMT), the at least one light-emitting diode (LED) may be provided on the carrier utilizing a slanted or sloped profile. Specifically, in some examples, the at least one light-emitting diode (LED) may be provided on slanted or slope profile of the carrier to enable the at least one light-emitting diode (LED) to be pointed (e.g., angled) towards a user's eye. It may be appreciated that in other examples, the profile may be flat as well (e.g., in an instance where the light-emitting diode may cover a one-hundred eighty (180) degree range).

It may be appreciated that, in some examples, by utilizing laser direct structuring (LDS) to create traces (e.g., the conductive traces 902) onto a carrier (e.g., the carrier 901), and by utilizing surface-mount technology (SMT) to couple one or more light-emitting diodes (LEDs) (e.g., the infrared (IR) light-emitting diodes 903a-903b) onto the carrier, a significant cost savings may be achieved in manufacturing. Specifically, in some examples, by eliminating a need for a ring portion of a flexible printed circuit (FPC) (e.g., the ring portion of the flexible printed circuit (FPC) 802 in FIG. 8A) to house the one or more light-emitting diodes (LEDs), the cost a flexible printed circuit (FPC) arrangement may be much lower and a form factor of a flexible printed circuit (FPC) arrangement may be manufactured to be much smaller.

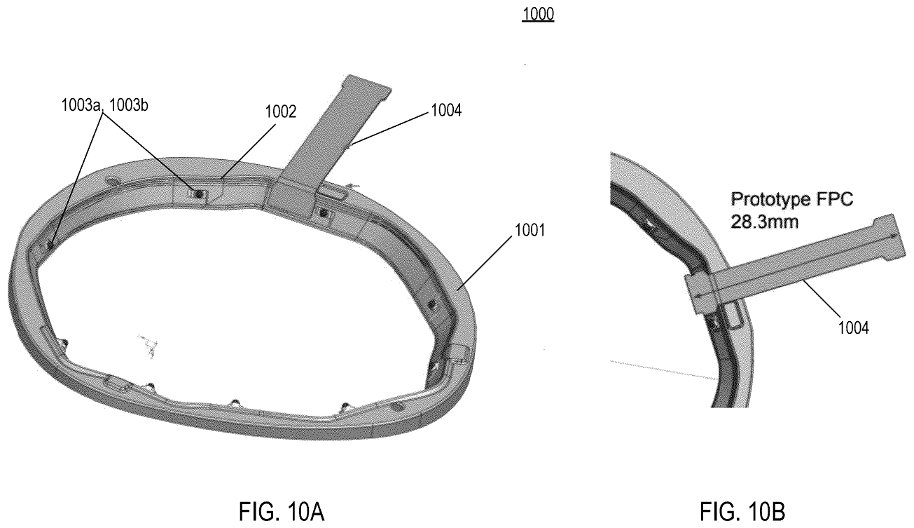

FIGS. 10A-10B illustrate various aspects of an eye tracking component 1000 having an extension flexible printed circuit, according to an example. In some examples, the eye tracking component 1000 may include a carrier 1001 that may include at least one conductive trace 1002 that may be printed (e.g., via laser direct structuring (LDS)), and may further include at least one light-emitting diode (LED) 1003a-1003b that may be attached (e.g., via surface-mount technology (SMT)).

In addition, in some examples, the eye tracking component 1000 may include an extension flexible printed circuit (FPC) 1004. In some examples, the extension flexible printed circuit (FPC) may be soldered on to the carrier 1001. In some examples, the extension flexible printed circuit (FPC) 1004 may be coupled to a (main) controller flexible printed circuit (FPC) (not shown), which may be used to, among other things, control various aspects of the operation of the at least one infrared (IR) light-emitting diode (LED) 1003a-1003b. In some examples, the extension flexible printed circuit (FPC) 1004 may be between twenty-five (25) to thirty (30) millimeters in length.

Accordingly, in some examples and as discussed above, the eye tracking component 1000 may eliminate a need for a “ring” portion of a flexible printed circuit (FPC) (e.g., the ring portion of a flexible printed circuit (FPC) 802 in FIG. 8A). Instead, in some examples, the systems and methods described herein may utilize an “extension” flexible printed circuit (FPC) having much a smaller form factor and weight to be operably coupled to a carrier and to control operation of at least one light-emitting diode (LED). As a result, in some examples, the systems and methods may eliminate some or all of the manufacturing inefficiencies (e.g., manually locating light-emitting diodes (LEDs) onto a carrier) and associated costs that may come with implementation of a display component configured to trace a user's eye.

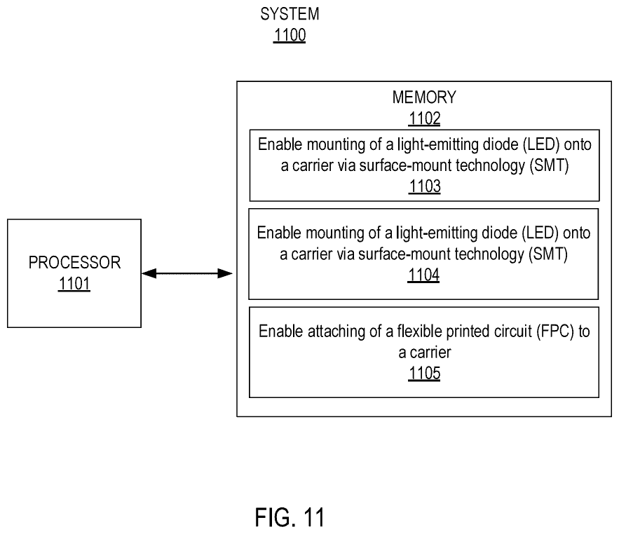

Reference is now made to FIG. 11. FIG. 11 illustrates a block diagram of a system, that may be implemented for implementing a conductive trace via laser direct structuring (LDS) and a light-emitting diode (LED) via surface-mount technology (SMT) on a carrier structure of a display device, according to an example.

While the servers, systems, subsystems, and/or other computing devices shown in FIG. 11 may be shown as single components or elements, it should be appreciated that one of ordinary skill in the art would recognize that these single components or elements may represent multiple components or elements, and that these components or elements may be connected via one or more networks. Also, middleware (not shown) may be included with any of the elements or components described herein. The middleware may include software hosted by one or more servers. Furthermore, it should be appreciated that some of the middleware or servers may or may not be needed to achieve functionality. Other types of servers, middleware, systems, platforms, and applications not shown may also be provided at the front-end or back-end to facilitate the features and functionalities of the system.

It should also be appreciated that the systems and methods described herein may be particularly suited for digital content, but are also applicable to a host of other distributed content or media. These may include, for example, content or media associated with data management platforms, search or recommendation engines, social media, and/or data communications involving communication of potentially personal, private, or sensitive data or information. These and other benefits will be apparent in the descriptions provided herein.

As shown in FIG. 11, the system 1100 may include processor 1101 and the memory 1102. In some examples, the processor 1101 may execute the machine-readable instructions stored in the memory 1102. It should be appreciated that the processor 1101 may be a semiconductor-based microprocessor, a central processing unit (CPU), an application specific integrated circuit (ASIC), a field-programmable gate array (FPGA), and/or other suitable hardware device.

In some examples, the memory 1102 may have stored thereon machine-readable instructions (which may also be termed computer-readable instructions) that the processor 1101 may execute. The memory 1102 may be an electronic, magnetic, optical, or other physical storage device that contains or stores executable instructions. The memory 1102 may be, for example, random access memory (RAM), an Electrically Erasable Programmable Read-Only Memory (EEPROM), a storage device, an optical disc, or the like. The memory 1102, which may also be referred to as a computer-readable storage medium, may be a non-transitory machine-readable storage medium, where the term “non-transitory” does not encompass transitory propagating signals. It should be appreciated that the memory 1102 depicted in FIG. 11 may be provided as an example. Thus, the memory 1102 may or may not include additional features, and some of the features described herein may be removed and/or modified without departing from the scope of the memory 1102 outlined herein.

It should be appreciated that, and as described further below, the processing performed via the instructions on the memory 1102 may or may not be performed, in part or in total, with the aid of other information and data. Moreover, and as described further below, it should be appreciated that the processing performed via the instructions on the memory 1102 may or may not be performed, in part or in total, with the aid of or in addition to processing provided by other devices.

In some examples, and as discussed further below, the instructions 1103-1105 on the memory 1102 may be executed alone or in combination by the processor 1101 to implementing a conductive trace via laser direct structuring (LDS) and a light-emitting diode (LED) via surface-mount technology (SMT) on a carrier structure of a display device.

In some examples, the instructions 1103 may enable printing of a conductive trace onto a carrier via laser direct structuring (LDS).

In some examples, the instructions 1104 may enable mounting of a light-emitting diode (LED) onto the carrier via surface-mount technology (SMT).

In some examples, the instructions 1105 may enable attaching of a flexible printed circuit (FPC) to the carrier, wherein a light-emitting diode (LED) may be communicatively coupled to a flexible printed circuit (FPC) via a conductive trace.

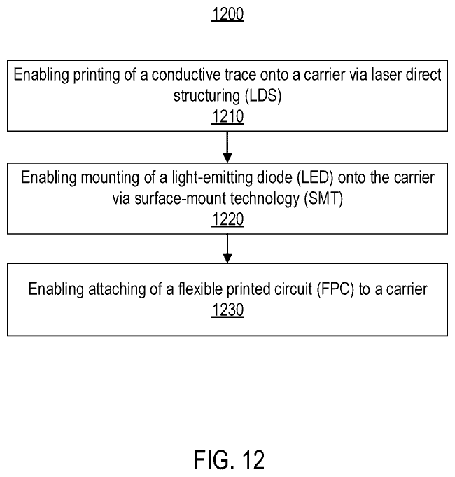

FIG. 12 illustrates a flow diagram of a method for a system, that may be implemented for implementing a conductive trace via laser direct structuring (LDS) and a light-emitting diode (LED) via surface-mount technology (SMT) on a carrier structure of a display device, according to an example. The method 1200 is provided by way of example, as there may be a variety of ways to carry out the method described herein. Each block shown in FIG. 12 may further represent one or more processes, methods, or subroutines, and at least one of the blocks may include machine-readable instructions stored on a non-transitory computer-readable medium and executed by a processor or other type of processing circuit to perform one or more operations described herein. Although the method 1200 is primarily described as being performed by system 1100 as shown in FIGS. 11, the method 1200 may be executed or otherwise performed by other systems, or a combination of systems.

Reference is now made with respect to FIG. 12. At 1210, the processor 101 may enable printing of a conductive trace onto a carrier via laser direct structuring (LDS). In some examples, the processor 101 may enable a laser etch that may provide a base for the one or more conductive traces, and then may plate the provided bases with copper to enable conductivity. It may be appreciated that, in some examples, the processor 101 may also provide an additional (e.g., nickel, gold) plating on top of the copper plating to protect the copper from corrosion.

At 1220, the processor 101 may enable mounting of a light-emitting diode (LED) onto the carrier via surface-mount technology (SMT).

At 1230, the processor 101 may enable attaching of a flexible printed circuit (FPC) to the carrier, wherein a light-emitting diode (LED) may be communicatively coupled to a flexible printed circuit (FPC) via a conductive trace.

Wearable devices, such as smartglasses, often include multiple types of electronic components including cameras, touch sensors, speakers, microphones, batteries, controllers, antennas, etc. In addition, there may be a relatively limited area of the wearable devices at which antennas may be positioned to maintain sufficient antenna efficiencies and specific absorption rates (SARs) of the antennas. That is, it may be difficult to maintain stable antenna performance when antennas are positioned too close to a hinge. Additionally, positioning the antennas too close to the hinge may cause manufacturing issues. Moreover, as the distance between a user's head and the temple arm of a pair of smartglasses often decreases significantly from a user's temple to a user's ear, e.g., from about 10 mm to about 3 mm, positioning the antennas close to the distal end of a temple arm may result in degradation of the SAR of the antenna.

As a result, it may often be difficult to integrate the various types of electronic components within a wearable device having a conventional form factor. Instead, it may be necessary to make some parts of the wearable device, such as the temple arms, have a relatively larger size to accommodate all of the electronic components. This issue may be exacerbated, for instance, when multiple types of antennas that may cover multiple bands of frequencies are integrated into the wearable devices. However, increasing the sizes of the parts of the wearable device may be unattractive to users due to the increased bulkiness of the wearable device as well as the potential impact on the aesthetics of the wearable device.

Disclosed herein are wearable devices with integrated antennas that are able to cover a relatively wide range of bandwidths, in which the wearable devices may have temple arms with relatively small or otherwise normal dimensions. Particularly, the wearable devices disclosed herein may include antennas integrated into temple arms that are able to cover the relatively wide range of bandwidths, e.g., WiFi, Bluetooth, ultra wideband (UWB), etc., while having relatively small form factors. The antennas disclosed herein may include a first radiating element and a second radiating element, in which the first radiating element and the second radiating element may be complementarily oriented in the same direction. As a result, the first radiating element and the second radiating element may fit in a relatively small space, e.g., almost half the space normally required (less than quarter-wavelength long, 0.25 times the wavelength). The antennas disclosed herein may also be a single-ended antenna and may thus not need a balun.

The first radiating elements and the second radiating elements of the antennas disclosed herein may have different lengths with respect to each other and may together interact with a multilayer board ground plane to cause efficient electromagnetic radiation over a wide frequency band. Additionally, an arc-shaped feed element may be employed to feed the first and second radiating elements. The configurations of the first radiating element and the second radiating element and the arrangement of the feed element with respect to the first and second radiating elements as disclosed herein may enable for a relatively strong electromagnetic coupling over a wide frequency band range to achieve ultra wide bandwidth coverage. In addition, the feed point of the feed element may be located asymmetrically on the hinge side and away from the distal end of the temple arm, which may enable a low SAR to be achieved.

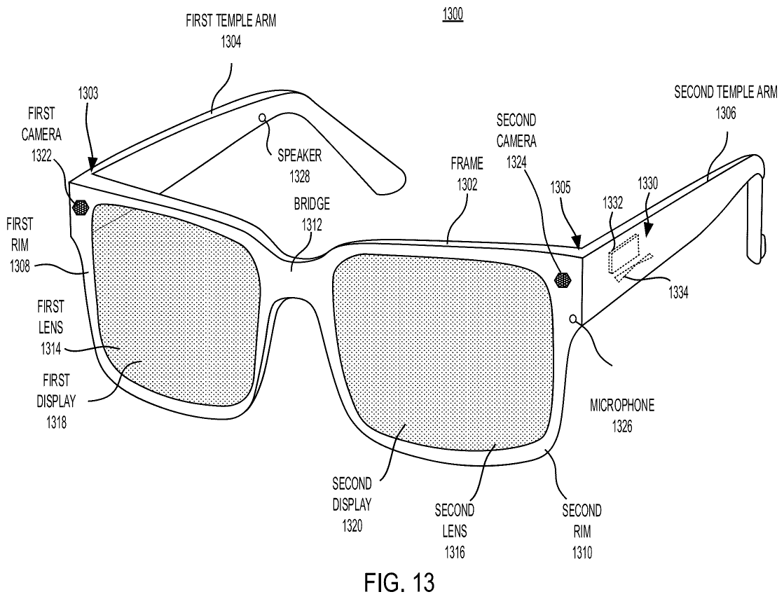

Reference is first made to FIG. 13, which illustrates a perspective view of a wearable device 1300 having an integrated antenna 1334, according to an example. The wearable device 1300 may be a wearable eyewear, a wearable headset, smartglasses, smart sunglasses, and/or the like. As shown, the wearable device 1300 may include a frame 1302, a first temple arm 1304, and a second temple arm 1306. The frame 1302 may include a first rim 1308, a second rim 1310, and a bridge 1312 that couples the first rim 1308 to the second rim 1310. In some examples, the frame 1302 is formed of a single, unitary, or integral piece of material, while in other examples, the frame 1302 is formed of multiple components fastened together with one or more mechanical fasteners (such as screws), adhesives, welding, and/or the like.

As shown in FIG. 13, the first temple arm 1304 may be coupled to the first rim 1308 of the frame 1302 at a first mounting location 1303 and the second temple arm 1306 may be coupled to the second rim 1310 of the frame 1302 at a second mounting location 1305. According to examples, the first temple arm 1304 may be coupled to the first rim 1308 through a first hinge (not shown) at the first mounting location 1303 such that the first temple arm 1304 may rotatably be moved with respect to the first rim 1308. That is, the first temple arm 1304 may rotate in a manner to cause the first temple arm 1304 to fold towards the frame 1302.

Likewise, the second temple arm 1306 may be coupled to the second rim 1310 through a second hinge (not shown) at the second mounting location 1305 such that the second temple arm 1306 may rotatably be moved with respect to the second rim 1310. That is, the second temple arm 1306 may rotate in a manner to cause the second temple arm 1306 to fold towards the frame 1302.

The first temple arm 1304 and the second temple arm 1306 may be moved to collapsed positions with respect to the frame 1302. This may be helpful when the wearable device 1300 is to be stored in a case or otherwise maintained in an unworn state. In other examples, the first temple arm 1304 and the second temple arm 1306 may inflexibly be coupled to the frame 1302 such that the first temple arm 1304 and the second temple arm 1306 may maintain fixed relationships with the frame 1302.

The first temple arm 1304 and the second temple arm 1306 may be configured to sit on and extend beyond a respective ear of a user of the wearable device 1300. The first temple arm 1304 and the second temple arm 1306 may therefore assist in holding the wearable device 1300 on a user's head such that the first rim 1308 and the second rim 1310 are positioned in front of the user's eyes.

The frame 1302 may further include a first lens 1314 mounted in the first rim 1308 and a second lens 1316 mounted in the second rim 1310. The first lens 1314 and the second lens 1316 may be mounted in the respective rims 1308, 1310 via an adhesive, an interference fit, a friction fit, a press fit, a heat/shrink fit, and/or the like. In some examples, the first lens 1314 and the second lens 1316 may be clear lenses, while in other examples, the first lens 1314 and the second lens 1316 may be tinted. Thus, for instance, the lenses 1314, 1316 may be cosmetic or prescription lenses and the wearable device 1300 may be prescription eyeglasses. In other examples in which the lenses 1314, 1316 are tinted, the wearable device 1300 may be sunglasses, either with prescription lenses or without prescription lenses.

In some examples, the wearable device 1300 may operate as a virtual reality display, an augmented reality display, and/or a mixed reality display. In these examples, the first lens 1314 may include a first display 1318 and the second lens 1316 may include a second display 1320. In some examples, the first and second displays 1318, 1320 may be configured to present media or other content to a user. In some examples, the first and second displays 1318, 1320 may include display electronics and/or display optics, e.g., a liquid crystal display (LCD) display panel, a light-emitting diode (LED) display panel, or an optical display panel (e.g., a waveguide display assembly). In some examples, the first and second displays 1318, 1320 may also include any of a number of optical components, such as waveguides, gratings, lenses, mirrors, etc. In some examples, the captured images may be processed, for example, by a virtual reality engine (not shown) to add virtual objects to the captured images or modify physical objects in the captured images, and the processed images may be displayed to the user by the first and second displays 1318, 1320 for augmented reality (AR) and/or mixed reality (MR) applications.

In some examples, the wearable device 1300 may include a first camera 1322. The first camera 1322 may capture images of the physical environment in the field of view of the first camera 1322. The captured images may be stored locally on the wearable device 1300, for instance, in a data store housed in the wearable device 1300. In addition, or alternatively, the captured images may be communicated to a companion device, such as a smart phone, a laptop, a tablet computer, a smart watch, and/or the like. The captured images may be communicated wirelessly to the companion device and/or may be communicated to the companion device through a wired connection. In some examples, the wearable device 1300 may continuously communicate the captured images to the companion device such that the captured images may be displayed and/or stored on the companion device nearly simultaneously with the capture of the images. In other examples, the wearable device 1300 may communicate the captured images at a time later than when the images are captured, for instance, after the wearable device 1300 is connected to the companion device.

As shown in FIG. 13, the wearable device 1300 may also include a second camera 1324. Images captured by the second camera 1324 may similarly be stored locally on the wearable device 1300 and/or communicated to the companion device. The first camera 1322 may be positioned on the frame 1302 near the first temple arm 1304 and the second camera 1324 may be positioned on the frame 1302 near the second temple arm 1306 such that stereoscopic images may be captured. The first camera 1322 and the second camera 1324 may be mounted to the frame 1302 through any suitable mounting mechanism, such as through friction fitting, interference fitting, an adhesive, press fitting, heat/shrink fitting, and/or the like. The first camera 1322 and the second camera 1324 may each include a charge coupled device (CCD), a complementary metal-oxide semiconductor (CMOS) digital image sensor and an optical element, or the like.

In some examples, the wearable device 1300 may include a microphone 1326 to capture audio signals. The captured audio signals may be stored locally on the wearable device 1300 and/or communicated to a companion device in manners similar to those discussed above with respect to the captured images. In addition, or alternatively, the wearable device 1300 may include one or more speakers 1328 to enable audio to be outputted to a user of the wearable device 1300. The one or more speakers 1328 may be positioned in the first temple arm 1304 and the second temple arm 1306 such that a user may hear the audio outputted from the one or speakers 1328 when the user is wearing the wearable device 1300.

According to examples, the second temple arm 1306 may include a hollow portion 1330 in which electronic components 1332 of the wearable device 1300 may be housed. The hollow portion 1330 may be provided adjacent to or otherwise near the location at which the second temple arm 1306 is mounted to the frame 1302. The first temple arm 1304 may also include a hollow portion in which electronic components 1332 may be housed. The hollow portion in the first temple arm 1304 may also be provided adjacent to or otherwise near the location at which the first temple arm 1304 is mounted to the frame 1302.

The electronic components 1332 may include a controller, such as a microprocessor, control circuitry, an application-specific integrated circuit, or the like. The controller may be mounted on a printed circuit board (PCB), such as a multilayer PCB printed circuit board or multilayer board (MLB). The electronic components 1332 may also or alternatively include a battery to supply power to various other electronic components 1332 in the wearable device 1300. The electronic components 1332 may further include radio components, such as a transmitter, receiver, or transceiver. The radio components may be coupled to one or more antennas 1334, which may provide connectivity between the wearable device 1300 and external electronic devices, such as a companion device, a wireless access point, a router, and/or the like.

According to examples, the one or more antennas 1334 may be configured to enable transmission and/or receipt of signals over WiFi bands, Bluetooth® bands, and/or ultra wideband (UWB). For instance, the one or more antennas 1334 may cover a relatively large frequency bandwidth, e.g., between about 2.4 GHz and 9 GHz. Additionally, the one or more antennas 1334 may be positioned away from the distal ends of the first temple arm 1304 and the second temple arm 1306 and closer to the frame 1302. In other words, the one or more antennas 1334 may be positioned at locations on the first temple arm 1304 and/or the second temple arm 1306 that are distant from a user's head when the user wears the wearable device 1300. As a result, relatively low specific absorption rates (SARs) by the one or more antennas 1334 may be achieved. In some examples, the antennas 1334 may be provided in both the first temple arm 1304 and the second temple arm 1306.

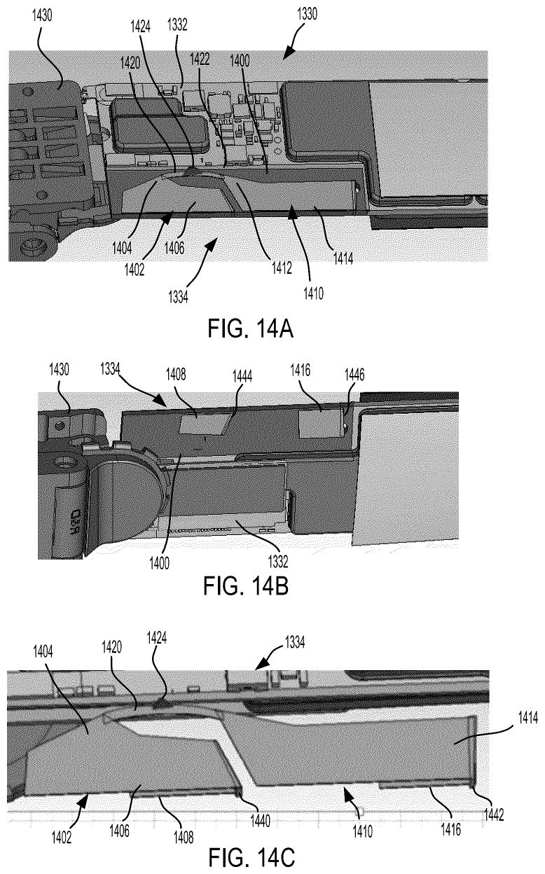

FIG. 14A illustrates a perspective view of the electronic components 1332 and the antenna 1334 housed in the hollow portion 1330 of a temple arm as shown in FIG. 13, according to an example. Particularly, FIG. 14A shows the electronic components 1332 and the antenna 1334 with a portion of the housing of a temple arm, e.g., the first temple arm 1304 or the second temple arm 1306, removed according to an example. FIG. 14A illustrates the antennas 1334 as facing outside of the wearable device 1300, e.g., away from the first temple arm 1304.

As shown in FIG. 14A, the electronic components 1332 may be mounted to, fabricated on, or the like, onto a substrate 1400. The substrate 1400 may be a substrate of a printed circuit board (PCB), a multilayer board (MLB), a multilayer printed circuit board (PCB), or the like. As also shown in FIG. 14A, the antenna 1334 may be formed on or otherwise mounted to the substrate 1400. In some examples in which the substrate 1400 is part of a multilayer board, the antenna 1334 may be formed from layers, e.g., copper layers, of the multilayer board.

According to examples, the antenna 1334 may include a first radiating element 1402 and a second radiating element 1410. The first radiating element 1402 and the second radiating element 1410 may be complementarily oriented in the same direction such that, for instance, the first radiating element 1402 and the second radiating element 1410 may fit in a relatively small space, e.g., less than a quarter-wavelength long, 0.25 times the wavelength. The antenna 1334 may also be a single-ended antenna and may not need a balun. As shown in FIG. 14A, the first radiating element 1402 may have a length that differs from the length of the second radiating element 1410 to enable the antenna 1334 to cause efficient electromagnetic radiation over a wide frequency band.

The first radiating element 1402 may have a first portion 1404 and a second portion 1406. The first portion 1404 of the first radiating element 1402 may be narrower than the second portion 1406 of the first radiating element 1402. As shown in FIG. 14A, the first portion 1404 and the second portion 1406 may be integral with each other such that there may not be a seam between the first portion 1404 and the second portion 1406. In addition, the first portion 1404 may be situated with respect to the second portion 1406 such that a tip of the first portion 1404 extends away from the second portion 1406. In some examples, and as shown in FIG. 14A, the first portion 1404 may include a generally triangular-shaped geometry and the second portion 1406 may include a generally rectangular-shaped geometry. In other examples, the first portion 1404 and the second portion 1406 may include other geometries.

The second radiating element 1410 may have a first section 1412 and a second section 1414, in which the second radiating element 1410 may have a shape that differs from the shape of the first radiating element 1402. The first section 1412 of the second radiating element 1410 may be narrower than the second section 1414 of the second radiating element 1410. As shown in FIG. 14A, the first section 1412 and the second section 1414 may be integral with each other such that there may not be a seam between the first section 1412 and the second section 1414. Additionally, the first section 1412 may be situated with respect to the second section 1414 such that a tip of the first section 1412 extends away from the second section 1414. In some examples, the first section 1412 may include a generally triangular-shaped geometry and the second section 1414 may include a generally rectangular-shaped geometry. In other examples, the first section 1412 and the second section 1414 may include other geometries.

The antenna 1334 may further include a feed element 1420 connected to the first portion 1404 of the first radiating element 1402 and the first section 1412 of the second radiating element 1410. In other words, the feed element 1420 may be connected to narrow sections of the first radiating element 1402 and the second radiating element 1410. The feed element 1420 may be connected to the first portion 1404 of the first radiating element 1402 and the first section 1412 of the second radiating element 1410 through welds, adhesives, mechanical fasteners, and/or the like.

In addition, the first radiating element 1402 may be separate from the second radiating element 1410 and the first and second radiating elements 1402, 1410 may only be connected to each other via the feed element 1420. The feed element 1420 may be connected to a ground line 1422 on the substrate 1400 such that the feed element 1420 may receive and send signals between the ground line 1422 and the first and second radiating elements 1402, 1410. The feed element 1420 may also directly and parasitically connect to the ground line 1422 at a feed trace 1424. As a result, the feed element 1420 may provide a single arc feed to both the first radiating element 1402 and the second radiating element 1410. In some examples, the feed element 1420 and the feed trace 1424 may be formed of a conductive material, such as copper, and the feed trace 1424 may be connected to the feed element 1420.

In one regard, the configurations of the first radiating element 1402 and the second radiating element 1410 and the arrangement of the feed element 1420 with respect to the first and second radiating elements 1402, 1410 may enable for a relatively strong electromagnetic coupling over a wide frequency band range to achieve ultra wide bandwidth coverage. In addition, the feed trace 1424 is located asymmetrically on the hinge side of the wearable device 1300 and away from the distal end of the temple arm, which may enable a low SAR to be achieved.

Also shown in FIG. 14A is a hinge 1430 of the wearable device 1300. The hinge 1430 may be positioned at the second mounting location 1305. That is, the hinge 1430 may be provided on the wearable device 1300 to rotatably connect the second temple arm 1306 to the frame 1302. In other words, a first part of the hinge 1430 may be connected to the frame 1302 and a second part of the hinge 1430 may be connected to the second temple arm 1306. The hinge 1430 may be connected to the frame 1302 and the second temple arm 1306 through any suitable connection mechanism. For instance, the hinge 1430 may be connected to the frame 1302 and the second temple arm 1306 through mechanical fasteners, adhesives, welds, and/or the like. In addition, a second hinge may be provided at the first mounting location 1303 and may be connected to the frame 1302 and the first temple arm 1304 in a similar manner.

The first and second radiating elements 1402, 1410 are depicted as being positioned near and oriented away from the hinge 1430. In one regard, by positioning the first and second radiating elements 1402, 1410 as well as the feed element 1420 near a temple area of the wearable device 1300, e.g., away from a user's ear and at a location that is farthest from the user's temple, a relatively low specific absorption rate may be achieved. Additionally, the orientations of the first and second radiating elements 1402, 1410 may prevent the first and second radiating elements 1402, 1410 from being susceptible to hinge types and states because the first and second radiating elements 1402, 1410 may not extend into contact with the hinge 1430. That is, the first and second radiating elements 1402, 1410 disclosed herein may be employed in wearable devices 1300 that have any of multiple types of hinges 1430 because the first and second radiating elements 1402, 1410 may not interfere with rotation of the hinges 1430.

As shown in FIG. 14A, the first radiating element 1402 may extend along a common plane with the second radiating element 1410. That is, the first radiating element 1402 and the second radiating element 1410 may be formed on a common surface of the substrate 1400, which may be relatively flat. In any regard, the first radiating element 1402, the second radiating element 1410, and the feed element 1420 may be formed of an electrically conductive material such as copper, gold, silver, nickel, aluminum, an alloy, or other suitable material. In some examples, the substrate 1400 may be formed of a dielectric material and the first and second radiating elements 1402, 1410 may be printed onto the substrate 1400. In addition, the first and second radiating elements 1402, 1410 may be copper traces plated with gold, silver, and/or nickel.

Reference is now made to FIGS. 14B and 14C. FIG. 14B illustrates a rear perspective view of the features depicted in FIG. 14A and FIG. 14C illustrates an enlarged view of the antenna 1334 depicted in FIGS. 14A and 14B, according to an example. As shown in FIG. 14B, the first radiating element 1402 may include a third portion 1408 that is positioned on an opposite side of the substrate 1400 as compared with the first and second portions 1404, 1406 of the first radiating element 1402. The third portion 1408 may extend away from the second radiating element 1410. In addition, the third portion 1408 may be connected to the second portion 1406 of the first radiating element 1402 through a via 1444 in the substrate 1400 such that edges of the second portion 1406 and the third portion 1408 are parallel or nearly parallel with each other.

As also shown in FIG. 14B, the second radiating element 1410 may include a third section 1416 that is positioned on an opposite side of the substrate 1400 as compared with the first and second sections 1412, 1414 of the second radiating element 1410. The third section 1416 may extend toward the first radiating element 1402. In addition, the third section 1416 may be connected to the second section 1414 of the second radiating element 1410 through a via 1446 in the substrate 1400 such that edges of the second section 1414 and the third section 1416 are parallel or nearly parallel with each other.

The arrangement of the third portion 1408 with respect to the second portion 1406 and the third section 1416 with respect to the second section 1414 is shown in FIG. 14C. As shown in FIG. 14C, the third portion 1408 may be connected to the second portion 1406 of the first radiating element 1402 by a first connection member 1440 and the third section 1416 may be connected to the second section 1414 of the second radiating element 1410 by a second connection member 1442. That is, the first connection member 1440 and the second connection member 1442 may extend through respective vias 1444, 1446 (FIG. 14B) in the substrate 1400. In one regard, the third portion 1408 of the first radiating element 1402 and the third section 1416 of the second radiating element 1410 may increase the surface areas of the first radiating element 1402 and the second radiating element 1410, which may enhance the magnetic permeability of the antenna 1334.

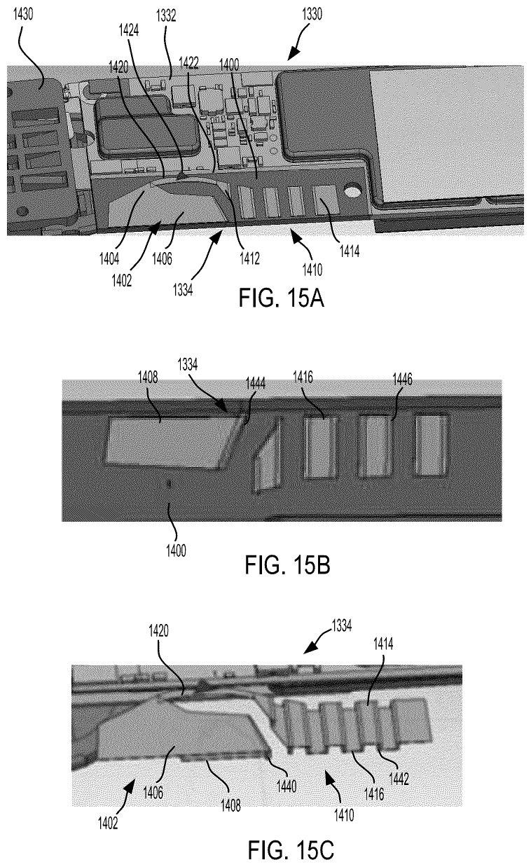

FIG. 15A illustrates a perspective view of the electronic components 1332 and the antenna 1334 housed in the hollow portion 1330 of a temple arm as shown in FIG. 13, according to an example. FIG. 15B illustrates a rear perspective view of the features depicted in FIG. 15A and FIG. 15C illustrates an enlarged view of the antenna 1334 depicted in FIG. 15A, according to an example.

FIGS. 15A-15C illustrate features similar to the features respectively illustrated in FIGS. 14A-14C. However, the antenna 1334 depicted in FIGS. 15A-15C differs from the antenna 1334 depicted in FIGS. 14A-14C in that the second radiating element 1410 depicted in FIGS. 15A-15C includes a plurality of second sections 1414, a plurality of third sections 1416, and a plurality of second connection members 1442. Particularly, the second radiating element 1410 shown in FIGS. 15A-15B may have a meandering or undulating configuration in which the plurality of second sections 1414 may be provided on a first surface of the substrate 1400 and the plurality of third sections 1416 may be provided on the opposite surface of the substrate 1400. Additionally, the second connection members 1442 may be provided in multiple vias 1446 in the substrate 1400. In other words, the second sections 1414, the third sections 1416, and the second connection members 1442 may be formed of several layers of the substrate 1400.

According to examples, the second sections 1414, the third sections 1416, and the second connection members 1442 may employ several copper layers of the multilayer board and the vias 1446 to make the antenna 1334 relatively compact by meandering portions of the second radiating element 1410. The meandering or undulating configuration of the second radiating element 1410 may better be seen in FIG. 15C. In one regard, by configuring the second radiating element 1410 to have a meandering or undulating configuration, magnetic permeability of the second radiating element 1410 may be enhanced. In other words, the meandering or undulating configuration may help to reduce a rate at which electromagnetic waves are propagated through the second radiating element 1410, which may enhance the magnetic permeability of the second radiating element 1410.

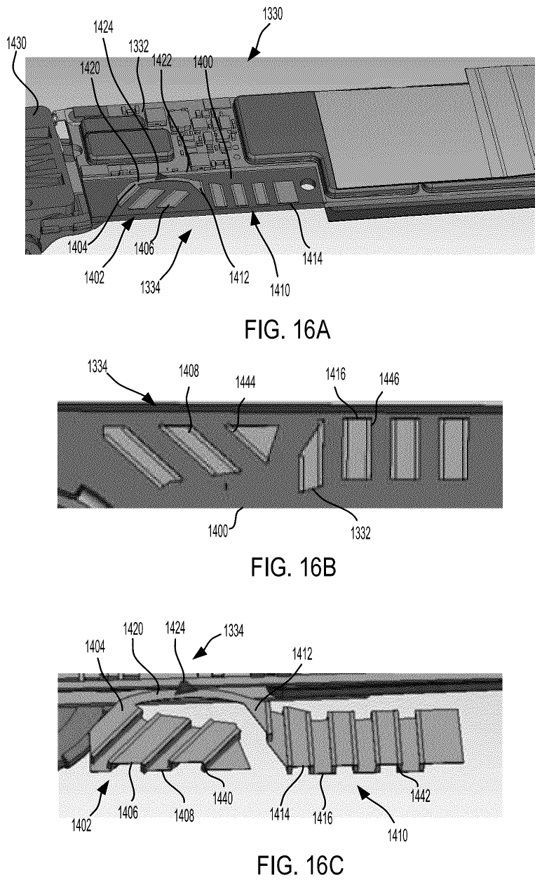

FIG. 16A illustrates a perspective view of the electronic components 1332 and the antenna 1334 housed in the hollow portion 1330 of a temple arm as shown in FIG. 13, according to an example. FIG. 16B illustrates a rear perspective view of the features depicted in FIG. 16A and FIG. 16C illustrates an enlarged view of the antenna 1334 depicted in FIG. 16A, according to an example.

FIGS. 16A-16C illustrate features similar to the features respectively illustrated in FIGS. 15A-15C. However, the antenna 1334 depicted in FIGS. 16A-16C differs from the antenna 1334 depicted in FIGS. 15A-15C in that the first radiating element 1402 depicted in FIGS. 16A-16C also includes a plurality of second portions 1406, a plurality of third portions 1408, and a plurality of first connection members 1440. Particularly, the first radiating element 1402 shown in FIGS. 16A-16B may have a meandering or undulating configuration in which the plurality of second portions 1406 may be provided on a first surface of the substrate 1400 and the plurality of third portions 1408 may be provided on the opposite surface of the substrate 1400. Additionally, the first connection members 1440 may be provided in multiple vias 1444 in the substrate 1400. In other words, the second portions 1406, the third portions 1408, and the first connection members 1440 may be formed of several layers of the substrate 1400.

According to examples, the second portions 1406, the third portions 1408, and the first connection members 1440 may employ several copper layers of the multilayer board and the vias 1444 to make the antenna 1334 relatively compact by meandering or undulating portions of the first radiating element 1402. The meandering or undulating configuration of the first radiating element 1402 may better be seen in FIG. 16C. In one regard, by configuring the first radiating element 1402 to have a meandering or undulating configuration, magnetic permeability of the first radiating element 1402 may be enhanced. This may also help to reduce a rate at which electromagnetic waves are propagated through the first radiating element 1402, which may enhance the magnetic permeability of the first radiating element 1402.

In some examples, the first radiating element 1402 may include a meandering or undulating configuration as shown in FIGS. 16A-16C and the second radiating element 1410 may have the configuration shown in FIGS. 16A-16C.

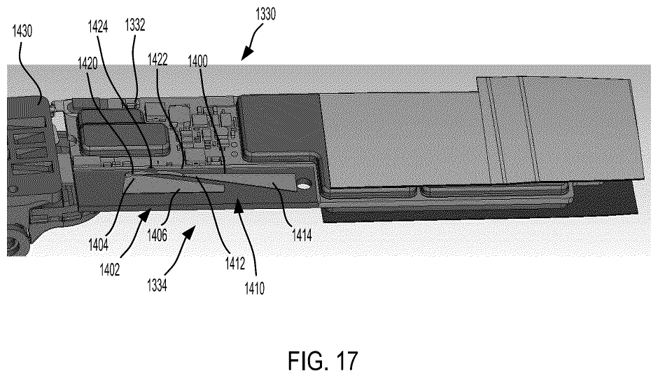

FIG. 17 illustrates a perspective view of the electronic components 1332 and the antenna 1334 housed in the hollow portion 1330 of the temple arm as shown in FIG. 13, according to an example. As shown in FIG. 17, the antenna 1334 may include a first radiating element 1402, a second radiating element 1410, and a feed element 1420. In addition, the first radiating element 1402 may include a first portion 1404 and a second portion 1406 and the second radiating element 1410 may include a first section 1412 and a second section 1414.

The feed element 1420 may be connected to the first portion 1404 of the first radiating element 1402 and the first section 1412 of the second radiating element 1410 in any of various manners as discussed herein. In addition, the first radiating element 1402 may be separate from second radiating element 1410 and may only be connected to each other via the feed element 1420 such that, for instance, the feed element 1420 may provide a single arc feed to the first radiating element 1402 and the second radiating element 1410.

As shown in FIG. 17, the first radiating element 1402 and the second radiating element 1410 may have relatively triangular shapes and may be positioned in a complementary arrangement with respect to each other. In other words, a portion of the second radiating element 1410 may overlap with a portion of the first radiating element 1402 along a lateral direction of the first temple arm 1304. As a result, the total length of the antenna 1334 may be reduced or minimized while maintaining sufficient area for the antenna 1334 to have an intended level of frequency bandwidth. Additionally, the first radiating element 1402 and the second radiating element 1410 may have different lengths with respect to each other and may together interact with a multilayer board ground plane to cause efficient electromagnetic radiation over a wide frequency band.

According to examples, a second antenna (not shown) may be housed within the first temple arm 1304. The second antenna may be positioned near the first mounting location 1303 and may be configured similarly to any of the configurations at which the antenna 1334 may be configured as shown in FIGS. 14A-17.

In the foregoing description, various inventive examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example’ is not necessarily to be construed as preferred or advantageous over other embodiments or designs.

Although the methods and systems as described herein may be directed mainly to digital content, such as videos or interactive media, it should be appreciated that the methods and systems as described herein may be used for other types of content or scenarios as well. Other applications or uses of the methods and systems as described herein may also include social networking, marketing, content-based recommendation engines, and/or other types of knowledge or data-driven systems.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims—and their equivalents—in which all terms are meant in their broadest reasonable sense unless otherwise indicated.

In the foregoing description, various examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example’ is not necessarily to be construed as preferred or advantageous over other embodiments or designs.

Augmented reality (AR), virtual reality (VR), and mixed reality (MR) are modern technologies with potential for significant impact(s) on humanity. Various display devices, such as smart glasses, may provide augmented reality (AR), virtual reality (VR), and mixed reality (MR) experiences to a user.

In some instances, a device (e.g., a pair of wearable smart glasses) may include a number of components including, but not limited to, a camera, a projector, a viewing lens, a microphone, and a battery. It may be appreciated that these elements may be arranged in the display device in a manner to enable use by a consumer. Specifically, it may be appreciated that aspects of a display device may be arranged such that a size, shape, and other physical specifications of components in the display device may provide maximum efficiency and comfort in use by a consumer. In some instances, this arrangement may be referred to as “form factor” for the device.

It may further be appreciated that, in some instance, one design aspect of a display device may conflict with another. For example, while a display device may benefit from a longer battery life, e.g., as provided by a larger battery unit, this may cause the body of the display device to become bulkier and/or heavier, and may cause discomfort to a user.

Accordingly, it may be beneficial to provide a design configuration that may maximize battery power while nevertheless providing a slim and pleasing appearance for a display device. To achieve this, one aspect of a display device (e.g., a pair of wearable smart eyeglasses) that may be addressed may be an arrangement of components within the display device.

One such component may be a temple arm provided in a display device, such as a pair of wearable eyeglasses. In some examples, a temple arm may be an elongated structure (or “stem”) of an eyewear frame that may connect a front of the eyewear to a user's head. In some examples, a “temple tip” may wrap around the back of the user's head, behind the user's ears, to secure the eyewear to the user's head.

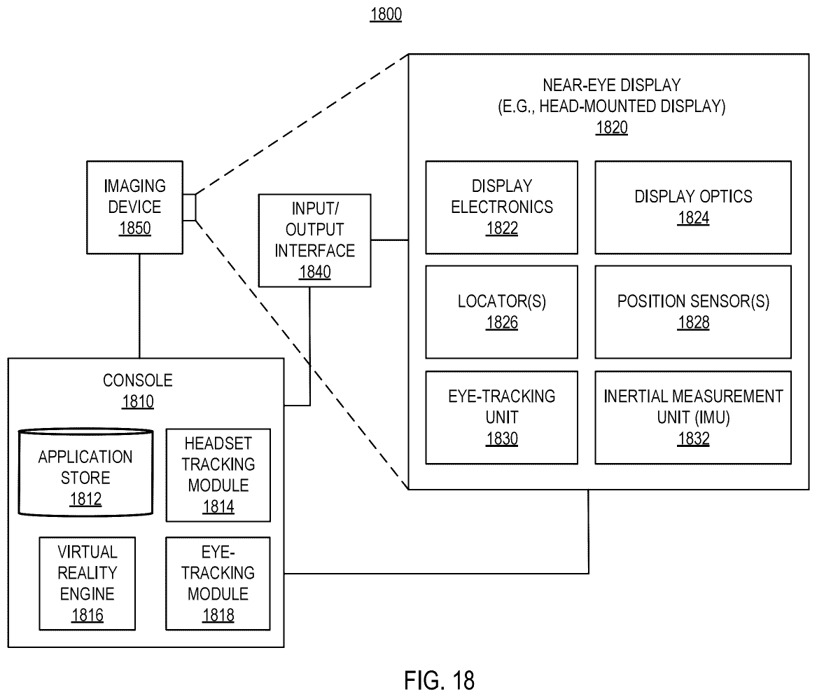

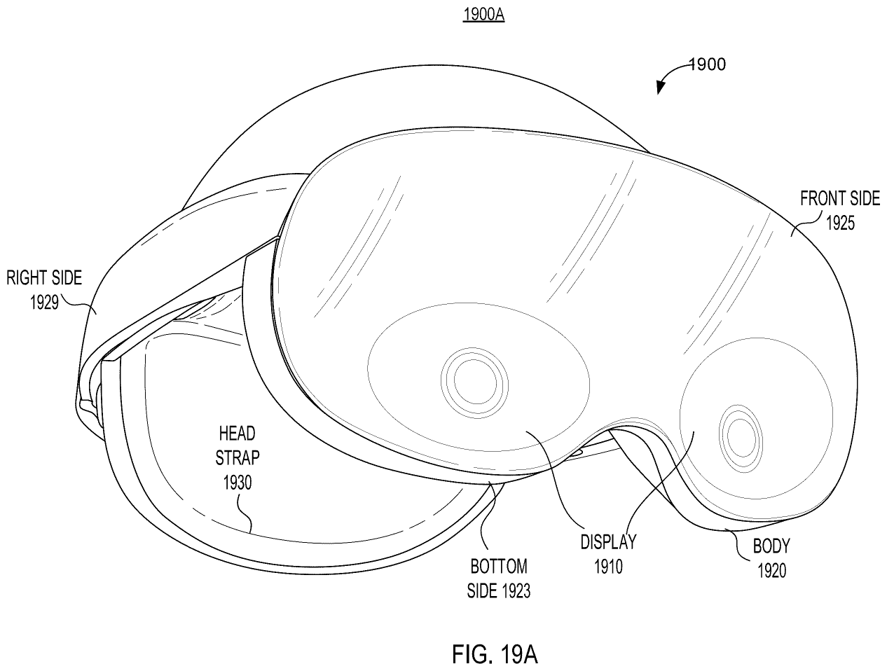

FIG. 18 illustrates a block diagram of an artificial reality system environment 1800 including a near-eye display device, according to an example. As used herein, a “near-eye display device” may refer to a device (e.g., an optical device) that may be in close proximity to a user's eye. As used herein, “artificial reality” may refer to aspects of, among other things, a “metaverse” or an environment of real and virtual elements and may include use of technologies associated with virtual reality (VR), augmented reality (AR), and/or mixed reality (MR). As used herein a “user” may refer to a user or wearer of a “near-eye display device.”

As shown in FIG. 18, the artificial reality system environment 1800 may include a near-eye display device 1820, an optional external imaging device 1850, and an optional input/output interface 1840, each of which may be coupled to a console 1810. The console 1810 may be optional in some instances as the functions of the console 1810 may be integrated into the near-eye display device 1820. In some examples, the near-eye display device 1820 may be a head-mounted display (HMD) that presents content to a user.

In some instances, for a near-eye display system, it may generally be desirable to expand an eye box, reduce display haze, improve image quality (e.g., resolution and contrast), reduce physical size, increase power efficiency, and increase or expand field of view (FOV). As used herein, “field of view” (FOV) may refer to an angular range of an image as seen by a user, which is typically measured in degrees as observed by one eye (for a monocular head-mounted display (HMD)) or both eyes (for binocular head-mounted displays (HMDs)). Also, as used herein, an “eye box” may be a two-dimensional box that may be positioned in front of the user's eye from which a displayed image from an image source may be viewed.

In some examples, in a near-eye display system, light from a surrounding environment may traverse a “see-through” region of a waveguide display (e.g., a transparent substrate) to reach a user's eyes. For example, in a near-eye display system, light of projected images may be coupled into a transparent substrate of a waveguide, propagate within the waveguide, and be coupled or directed out of the waveguide at one or more locations to replicate exit pupils and expand the eye box.

In some examples, the near-eye display device 1820 may include one or more rigid bodies, which may be rigidly or non-rigidly coupled to each other. In some examples, a rigid coupling between rigid bodies may cause the coupled rigid bodies to act as a single rigid entity, while in other examples, a non-rigid coupling between rigid bodies may allow the rigid bodies to move relative to each other.

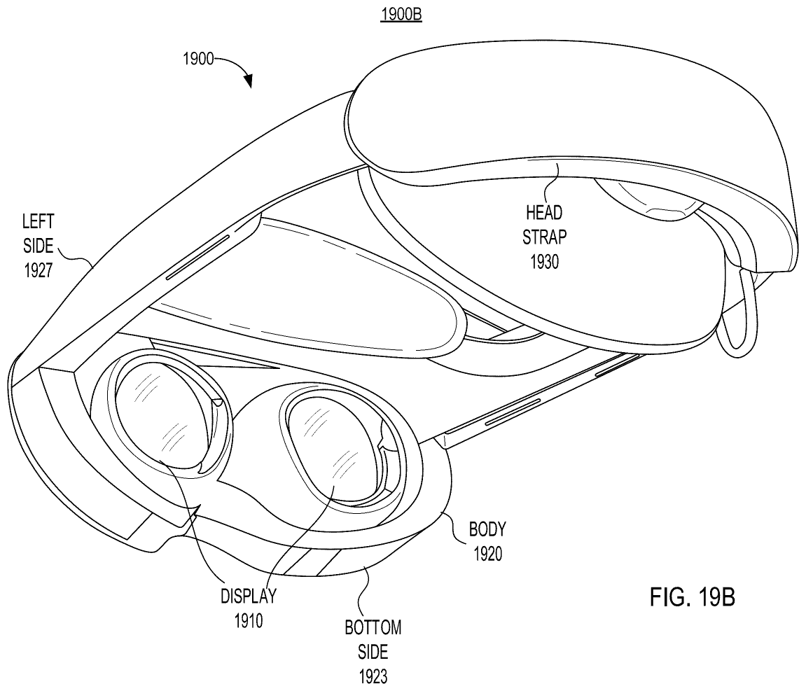

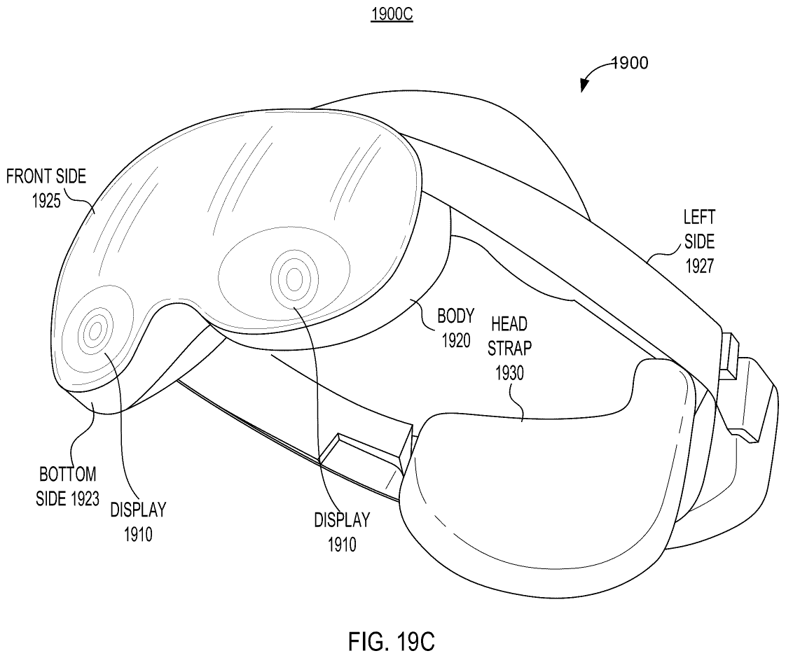

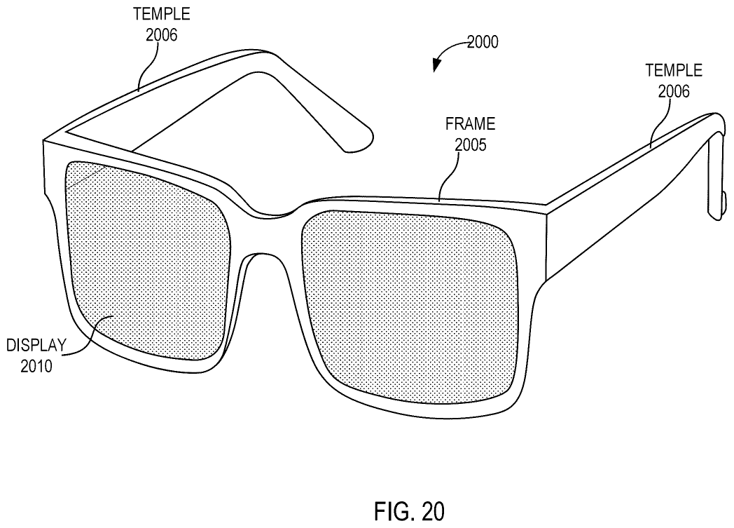

In some examples, the near-eye display device 1820 may be implemented in any suitable form-factor, including a head-mounted display (HMD), a pair of glasses, or other similar wearable eyewear or device. Examples of the near-eye display device 1820 are further described below with respect to FIGS. 19 and 20. Additionally, in some examples, the functionality described herein may be used in a head-mounted display (HMD) or headset that may combine images of an environment external to the near-eye display device 1820 and artificial reality content (e.g., computer-generated images). Therefore, in some examples, the near-eye display device 1820 may augment images of a physical, real-world environment external to the near-eye display device 1820 with generated and/or overlaid digital content (e.g., images, video, sound, etc.) to present an augmented reality to a user.

In some examples, the near-eye display device 1820 may include any number of display electronics 1822, display optics 1824, and an eye tracking unit 1830. In some examples, the near-eye display device 1820 may also include one or more locators 1826, one or more position sensors 1828, an inertial measurement unit (IMU) 1832, and a wireless communication subs-system 1834. In some examples, the near-eye display device 1820 may omit any of the eye tracking unit 1830, the one or more locators 1826, the one or more position sensors 1828, and the inertial measurement unit (IMU) 1832, or may include additional elements.

In some examples, the display electronics 1822 may display or facilitate the display of images to the user according to data received from, for example, the optional console 1810. In some examples, the display electronics 1822 may include one or more display panels. In some examples, the display electronics 1822 may include any number of pixels to emit light of a predominant color such as red, green, blue, white, or yellow. In some examples, the display electronics 1822 may display a three-dimensional (3D) image, e.g., using stereoscopic effects produced by two-dimensional panels, to create a subjective perception of image depth.

In some examples, the near-eye display device 1820 may include a projector (not shown), which may form an image in angular domain for direct observation by a viewer's eye through a pupil. The projector may employ a controllable light source (e.g., a laser) and a micro-electromechanical system (MEMS) beam scanner to create a light field from, for example, a collimated light beam. In some examples, the same projector or a different projector may be used to project a fringe pattern on the eye, which may be captured by a camera and analyzed (e.g., by the eye tracking unit 1830) to determine a position of the eye (the pupil), a gaze, etc.

In some examples, the display optics 1824 may display image content optically (e.g., using optical waveguides and/or couplers) or magnify image light received from the display electronics 1822, correct optical errors associated with the image light, and/or present the corrected image light to a user of the near-eye display device 1820. In some examples, the display optics 1824 may include a single optical element or any number of combinations of various optical elements as well as mechanical couplings to maintain relative spacing and orientation of the optical elements in the combination. In some examples, one or more optical elements in the display optics 1824 may have an optical coating, such as an anti-reflective coating, a reflective coating, a filtering coating, and/or a combination of different optical coatings.

In some examples, the display optics 1824 may also be designed to correct one or more types of optical errors, such as two-dimensional optical errors, three-dimensional optical errors, or any combination thereof. Examples of two-dimensional errors may include barrel distortion, pincushion distortion, longitudinal chromatic aberration, and/or transverse chromatic aberration. Examples of three-dimensional errors may include spherical aberration, chromatic aberration field curvature, and astigmatism.

In some examples, the one or more locators 1826 may be objects located in specific positions relative to one another and relative to a reference point on the near-eye display device 1820. In some examples, the optional console 1810 may identify the one or more locators 1826 in images captured by the optional external imaging device 1850 to determine the artificial reality headset's position, orientation, or both. The one or more locators 1826 may each be a light-emitting diode (LED), a corner cube reflector, a reflective marker, a type of light source that contrasts with an environment in which the near-eye display device 1820 operates, or any combination thereof.

In some examples, the external imaging device 1850 may include one or more cameras, one or more video cameras, any other device capable of capturing images including the one or more locators 1826, or any combination thereof. The optional external imaging device 1850 may detect light emitted or reflected from the one or more locators 1826 in a field of view of the optional external imaging device 1850.

In some examples, the one or more position sensors 1828 may generate one or more measurement signals in response to motion of the near-eye display device 1820. Examples of the one or more position sensors 1828 may include any number of accelerometers, gyroscopes, magnetometers, and/or other motion-detecting or error-correcting sensors, or any combination thereof.

In some examples, the inertial measurement unit (IMU) 1832 may be an electronic device that generates fast calibration data based on measurement signals received from the one or more position sensors 1828. The one or more position sensors 1828 may be located external to the inertial measurement unit (IMU) 1832, internal to the inertial measurement unit (IMU) 1832, or any combination thereof. Based on the one or more measurement signals from the one or more position sensors 1828, the inertial measurement unit (IMU) 1832 may generate fast calibration data indicating an estimated position of the near-eye display device 1820 that may be relative to an initial position of the near-eye display device 1820. For example, the inertial measurement unit (IMU) 1832 may integrate measurement signals received from accelerometers over time to estimate a velocity vector and integrate the velocity vector over time to determine an estimated position of a reference point on the near-eye display device 1820. Alternatively, the inertial measurement unit (IMU) 1832 may provide the sampled measurement signals to the optional console 1810, which may determine the fast calibration data.

The eye tracking unit 1830 may include one or more eye tracking systems. As used herein, “eye tracking” may refer to determining an eye's position or relative position, including orientation, location, and/or gaze of a user's eye. In some examples, an eye tracking system may include an imaging system that captures one or more images of an eye and may optionally include a light emitter, which may generate light (e.g., a fringe pattern) that is directed to an eye such that light reflected by the eye may be captured by the imaging system (e.g., a camera). In other examples, the eye tracking unit 1830 may capture reflected radio waves emitted by a miniature radar unit. These data associated with the eye may be used to determine or predict eye position, orientation, movement, location, and/or gaze.

In some examples, the wireless communication sub-system 1834 may include an ultra-wide band (UWB) transceiver. Ultra-wide band (UWB) wireless communication technology is used for short-range, fast, and secure data transmission environments. Ultra-wide band (UWB) wireless communication technology provides high transmission speed, low power consumption, and large bandwidth, in addition to the ability to co-exist with other wireless transmission technologies. The ultra-wide band (UWB) transceiver may be used to detect another user (head-mounted display (HMD) device) within range of communication and within an angle-of-arrival (AoA), then establish line-of-sight (LoS) communication between the two users. The communication may be in audio mode only or in audio/video mode. In other examples, the ultra-wide band (UWB) transceiver may be used to detect the other user, but a different communication technology (transceiver) such as WiFi or Bluetooth Low Energy (BLE) may be used to facilitate the line-of-sight (LOS) communication. In some cases, multiple wireless communication transceivers may be available and one with lowest power consumption, highest communication quality (e.g., based on interfering signals), or user choice may be used. For example, the communication technology may be selected based on a lowest power consumption for a given range.

In some examples, the input/output interface 1840 may be a device that allows a user to send action requests to the optional console 1810. As used herein, an “action request” may be a request to perform a particular action. For example, an action request may be to start or to end an application or to perform a particular action within the application. The input/output interface 1840 may include one or more input devices. Example input devices may include a keyboard, a mouse, a game controller, a glove, a button, a touch screen, or any other suitable device for receiving action requests and communicating the received action requests to the optional console 1810. In some examples, an action request received by the input/output interface 1840 may be communicated to the optional console 1810, which may perform an action corresponding to the requested action.

In some examples, the optional console 1810 may provide content to the near-eye display device 1820 for presentation to the user in accordance with information received from one or more of external imaging device 1850, the near-eye display device 1820, and the input/output interface 1840. For example, in the example shown in FIG. 18, the optional console 1810 may include an application store 1812, a headset tracking module 1814, a virtual reality engine 1816, and an eye tracking module 1818. Some examples of the optional console 1810 may include different or additional modules than those described in conjunction with FIG. 18. Functions further described below may be distributed among components of the optional console 1810 in a different manner than is described here.

In some examples, the optional console 1810 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In some examples, the modules of the optional console 1810 described in conjunction with FIG. 18 may be encoded as instructions in the non-transitory computer-readable storage medium that, when executed by the processor, cause the processor to perform the functions further described below. It should be appreciated that the optional console 1810 may or may not be needed or the optional console 1810 may be integrated with or separate from the near-eye display device 1820.

In some examples, the application store 1812 may store one or more applications for execution by the optional console 1810. An application may include a group of instructions that, when executed by a processor, generates content for presentation to the user. Examples of the applications may include gaming applications, conferencing applications, video playback application, or other suitable applications.

In some examples, the virtual reality engine 1816 may execute applications within the artificial reality system environment 1800 and receive position information of the near-eye display device 1820, acceleration information of the near-eye display device 1820, velocity information of the near-eye display device 1820, predicted future positions of the near-eye display device 1820, or any combination thereof from the headset tracking module 1814. In some examples, the virtual reality engine 1816 may also receive estimated eye position and orientation information from the eye tracking module 1818. Based on the received information, the virtual reality engine 1816 may determine content to provide to the near-eye display device 1820 for presentation to the user.

In some examples, the eye tracking module 1818, which may be implemented as a processor, may receive eye tracking data from the eye tracking unit 1830 and determine the position of the user's eye based on the eye tracking data. In some examples, the position of the eye may include an eye's orientation, location, or both relative to the near-eye display device 1820 or any element thereof. So, in these examples, because the eye's axes of rotation change as a function of the eye's location in its socket, determining the eye's location in its socket may allow the eye tracking module 1818 to more accurately determine the eye's orientation.

In some examples, a location of a projector of a display system may be adjusted to enable any number of design modifications. For example, in some instances, a projector may be located in front of a viewer's eye (e.g., “front-mounted” placement). In a front-mounted placement, in some examples, a projector of a display system may be located away from a user's eyes (e.g., “world-side”). In some examples, a head-mounted display (HMD) device may utilize a front-mounted placement to propagate light towards a user's eye(s) to project an image.

FIGS. 19A through 19C illustrate various views of a near-eye display device in the form of a head-mounted display (HMD) device 1900, according to an example. In some examples, the head-mounted device (HMD) device 1900 may be a part of a virtual reality (VR) system, an augmented reality (AR) system, a mixed reality (MR) system, another system that uses displays or wearables, or any combination thereof. In some examples, the head-mounted display (HMD) device 1900 may include a body 1920 and a head strap 1930. FIG. 19 shows a bottom side 1923, a front side 1925, and a left side 1927 of the body 1920 in the perspective view. In some examples, the head strap 1930 may have an adjustable or extendible length. In particular, in some examples, there may be a sufficient space between the body 1920 and the head strap 1930 of the head-mounted display (HMD) device 1900 for allowing a user to mount the head-mounted display (HMD) device 1900 onto the user's head. For example, the length of the head strap 1930 may be adjustable to accommodate a range of user head sizes. In some examples, the head-mounted display (HMD) device 1900 may include additional, fewer, and/or different components.

In some examples, the head-mounted display (HMD) device 1900 may present, to a user, media or other digital content including virtual and/or augmented views of a physical, real-world environment with computer-generated elements. Examples of the media or digital content presented by the head-mounted display (HMD) device 1900 may include images (e.g., two-dimensional (2D) or three-dimensional (3D) images), videos (e.g., 2D or 3D videos), audio, or any combination thereof. In some examples, the images and videos may be presented to each eye of a user by one or more display assemblies (not shown in FIG. 19) enclosed in the body 1920 of the head-mounted display (HMD) device 1900.

In some examples, the head-mounted display (HMD) device 1900 may include various sensors (not shown), such as depth sensors, motion sensors, position sensors, and/or eye tracking sensors. Some of these sensors may use any number of structured or unstructured light patterns for sensing purposes. In some examples, the head-mounted display (HMD) device 1900 may include an input/output interface 1840 for communicating with a console 1810, as described with respect to FIG. 18. In some examples, the head-mounted display (HMD) device 1900 may include a virtual reality engine (not shown), but similar to the virtual reality engine 1816 described with respect to FIG. 18, that may execute applications within the head-mounted display (HMD) device 1900 and receive depth information, position information, acceleration information, velocity information, predicted future positions, or any combination thereof of the head-mounted display (HMD) device 1900 from the various sensors.

In some examples, the information received by the virtual reality engine 1816 may be used for producing a signal (e.g., display instructions) to the one or more display assemblies. In some examples, the head-mounted display (HMD) device 1900 may include locators (not shown), but similar to the locators 1826 described in FIG. 18, which may be located in fixed positions on the body 1920 of the head-mounted display (HMD) device 1900 relative to one another and relative to a reference point. Each of the locators may emit light that is detectable by an external imaging device. This may be useful for the purposes of head tracking or other movement/orientation. It should be appreciated that other elements or components may also be used in addition or in lieu of such locators.

It should be appreciated that in some examples, a projector mounted in a display system may be placed near and/or closer to a user's eye (e.g., “eye-side”). In some examples, and as discussed herein, a projector for a display system shaped liked eyeglasses may be mounted or positioned in a temple arm (e.g., a top far corner of a lens side) of the eyeglasses. It should be appreciated that, in some instances, utilizing a back-mounted projector placement may help to reduce size or bulkiness of any required housing required for a display system, which may also result in a significant improvement in user experience for a user.

In some examples, the line-of-sight (LoS) transceiver 1918 may be part of a wireless communication sub-system such as the wireless communication sub-system and may be ultra-wide band (UWB) transceiver. The line-of-sight (LoS) transceiver 1918 may be used to detect another user (head-mounted display (HMD) device) within range of communication and within an angle-of-arrival (AoA), then establish line-of-sight (LoS) communication between the two users. The communication may be in audio mode only or in audio/video mode. In other examples, the line-of-sight (LOS) transceiver 1918 may be used to detect the other user, but a different (transceiver) such as WiFi or Bluetooth Low Energy (BLE) may be used to facilitate the line-of-sight (LoS) communication. In some cases, multiple wireless communication transceivers may be available and one with lowest power consumption, highest communication quality (e.g., based on interfering signals), or user choice may be used.

FIG. 20 is a perspective view of a near-eye display 2000 in the form of a pair of glasses (or other similar eyewear), according to an example. In some examples, the near-eye display 2000 may be a specific implementation of near-eye display 1820 of FIG. 18, and may be configured to operate as a virtual reality display, an augmented reality display, and/or a mixed reality display.

In some examples, the near-eye display 2000 may include a frame 2005 and a display 2010. In some examples, the display 2010 may be configured to present media or other content to a user. In some examples, the display 2010 may include display electronics and/or display optics, similar to components described with respect to FIGS. 18-19. For example, as described above with respect to the near-eye display 1820 of FIG. 1, the display 2010 may include a liquid crystal display (LCD) display panel, a light-emitting diode (LED) display panel, or an optical display panel (e.g., a waveguide display assembly). In some examples, the display 2010 may also include any number of optical components, such as waveguides, gratings, lenses, mirrors, etc.

In some examples, the near-eye display 2000 may further include various sensors 2050a, 2050b, 2050c, 2050d, and 2050e on or within a frame 2005. In some examples, the various sensors 2050a-2050e may include any number of depth sensors, motion sensors, position sensors, inertial sensors, and/or ambient light sensors, as shown. In some examples, the various sensors 2050a-2050e may include any number of image sensors configured to generate image data representing different fields of views in one or more different directions. In some examples, the various sensors 2050a-2050e may be used as input devices to control or influence the displayed content of the near-eye display 2000, and/or to provide an interactive virtual reality (VR), augmented reality (AR), and/or mixed reality (MR) experience to a user of the near-eye display 2000. In some examples, the various sensors 2050a-2050e may also be used for stereoscopic imaging or other similar application.

In some examples, the near-eye display 2000 may further include one or more illuminators 2030 to project light into a physical environment. The projected light may be associated with different frequency bands (e.g., visible light, infra-red light, ultra-violet light, etc.), and may serve various purposes. In some examples, the one or more illuminators 2030 may be used as locators, such as the one or more locators 1826 described above with respect to FIGS. 18-19.

In some examples, the near-eye display 2000 may also include a camera 2040 or other image capture unit. The camera 2040, for instance, may capture images of the physical environment in the field of view. In some instances, the captured images may be processed, for example, by a virtual reality engine (e.g., the virtual reality engine 1816 of FIG. 18) to add virtual objects to the captured images or modify physical objects in the captured images, and the processed images may be displayed to the user by the display 2010 for augmented reality (AR) and/or mixed reality (MR) applications.

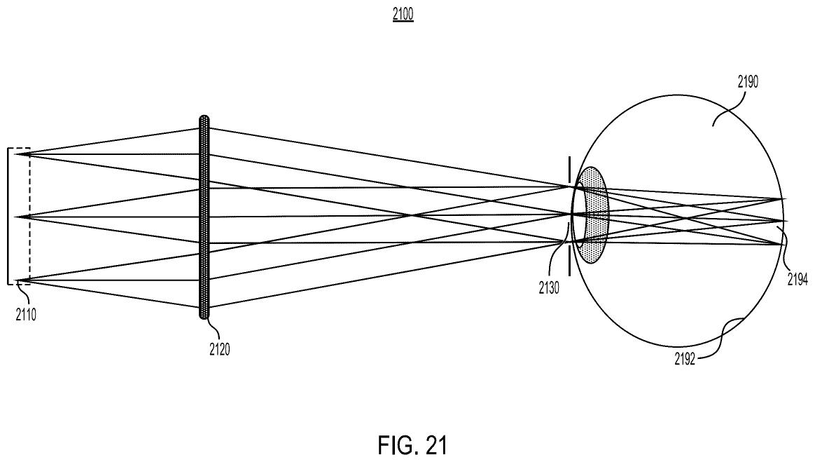

FIG. 21 illustrates a schematic diagram of an optical system 2100 in a near-eye display system, according to an example. In some examples, the optical system 2100 may include an image source 2110 and any number of projector optics 2120 (which may include waveguides having gratings as discussed herein). In the example shown in FIG. 21, the image source 2110 may be positioned in front of the projector optics 2120 and may project light toward the projector optics 2120. In some examples, the image source 2110 may be located outside of the field of view (FOV) of a user's eye 2190. In this case, the projector optics 2120 may include one or more reflectors, refractors, or directional couplers that may deflect light from the image source 2110 that is outside of the field of view (FOV) of the user's eye 2190 to make the image source 2110 appear to be in front of the user's eye 2190. Light from an area (e.g., a pixel or a light emitting device) on the image source 2110 may be collimated and directed to an exit pupil 2130 by the projector optics 2120. Thus, objects at different spatial locations on the image source 2110 may appear to be objects far away from the user's eye 2190 in different viewing angles (e.g., fields of view (FOV)). The collimated light from different viewing angles may then be focused by the lens of the user's eye 2190 onto different locations on retina 2192 of the user's eye 2190. For example, at least some portions of the light may be focused on a fovea 2194 on the retina 2192. Collimated light rays from an area on the image source 2110 and incident on the user's eye 2190 from a same direction may be focused onto a same location on the retina 2192. As such, a single image of the image source 2110 may be formed on the retina 2192.

In some instances, a user experience of using an artificial reality system may depend on several characteristics of the optical system, including field of view (FOV), image quality (e.g., angular resolution), size of the eyebox (to accommodate for eye and head movements), and brightness of the light (or contrast) within the eyebox. Also, in some examples, to create a fully immersive visual environment, a large field of view (FOV) may be desirable because a large field of view (FOV) (e.g., greater than about) 60° may provide a sense of “being in” an image, rather than merely viewing the image. In some instances, smaller fields of view may also preclude some important visual information. For example, a head-mounted display (HMD) system with a small field of view (FOV) may use a gesture interface, but users may not readily see their hands in the small field of view (FOV) to be sure that they are using the correct motions or movements. On the other hand, wider fields of view may require larger displays or optical systems, which may influence the size, weight, cost, and/or comfort of the head-mounted display (HMD) itself.

In some examples, a waveguide may be utilized to couple light into and/or out of a display system. In particular, in some examples and as described further below, light of projected images may be coupled into or out of the waveguide using any number of reflective or diffractive optical elements, such as gratings. For example, as described further below, one or more volume Bragg gratings (VBGs) may be utilized in a waveguide-based, back-mounted display system (e.g., a pair of glasses or similar eyewear).

In some examples, one or more volume Bragg gratings (VBGs) (or two portions of a same grating) may be used to diffract display light from a projector to a user's eye. Furthermore, in some examples, the one or more volume Bragg gratings (VBGs) may also help compensate for any dispersion of display light caused by each other to reduce the overall dispersion in a waveguide-based display system.

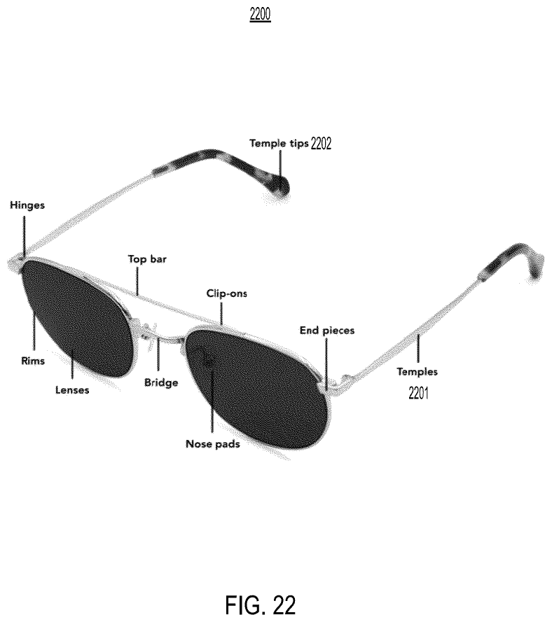

FIG. 22 illustrates components of a pair of wearable glasses 2200, including a pair of temple arms 2201 and a pair of temple tips 2202, according to an example. FIG. 22 also illustrates a hinge, a rim a lens, a top bar, a bridge, a clip-on, a nose pad, and an end-piece of the wearable glasses 2200 as well.

In some instances, temple arms of glasses may be made wider (or thicker). For example, in some instances, this may be for aesthetic and/or functional purposes.

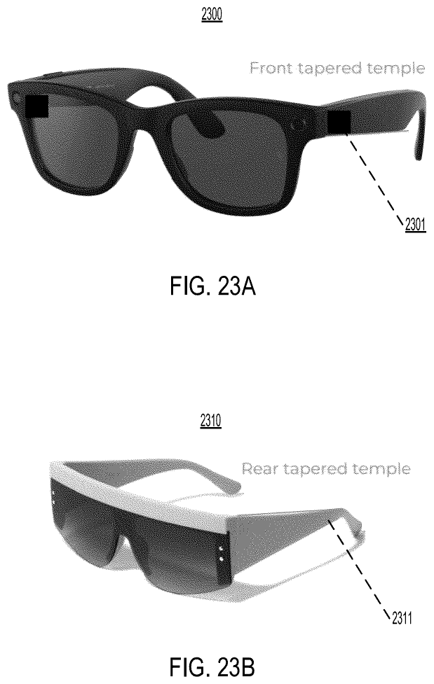

In some examples, for aesthetic and/or functional purposes, a temple arm of a pair of glasses may be made to “taper” from one end to another. So, in some examples, the temple arm may taper from wider width towards the rear (e.g., near a user's ear) to a narrower width towards the front (e.g., near a user's temple). In some instances, this may be referred to as “front tapered.” FIG. 23A illustrates a pair of eyeglasses 2300 having a front tapering 2301, according to an example.

In addition, in some instances, a temple arm may taper from wider width towards the front to a narrower width towards the rear. In some instances, this may be referred to as “rear tapered.” FIG. 23B illustrates a pair of eyeglasses 2310 having a rear tapering 2311, according to an example.

In some instances, tapered profiles may be popular option for design of smart glasses because a tapered profile may facilitate inclusion (and function) of various necessary electronic elements of the smart glass.

So, in some instances, a majority of electronic components of a pair of smart glasses, such as a camera, projector, lens, etc., may be included in the frame of the smart glasses (e.g., a top bar, a bridge, a rim, a lens, etc.). In some examples, this may lead the frame to becoming bulky, and thereby uncomfortable to a user.

In some examples, a tapered temple arm may be utilized to house various components of a pair of smart glasses. Examples of these components include, but are not limited to, a speaker, a battery, a microphone, and a battery management unit (BMU). In some examples and as used herein, a battery management unit (BMU) may be an electronic system that may be used to manage charging and discharging of a battery (e.g., a lead acid battery). In some examples, the battery management unit (BMU) may, among other things, monitor a state of the battery, determine and report data associated with the battery, and provide environmental control(s) for the battery.

It may be appreciated that a tapering profile of a temple arm may be provided, in some cases, based on design considerations for a smart glass. For example, in some cases, a microphone or speaker may often be placed towards a rear of a temple arm, near a user's ear. As such, in many cases, a battery may be more likely to be placed near a front of the temple arm.

Accordingly, in a design case where a sound quality or volume may be a priority, a more substantial (e.g., powerful) microphone or speaker may be facilitated via use of a front tapered temple arm design. Conversely, in a design case where battery life may be a priority, a larger battery unit may be facilitated via use of a rear tapered temple arm design.

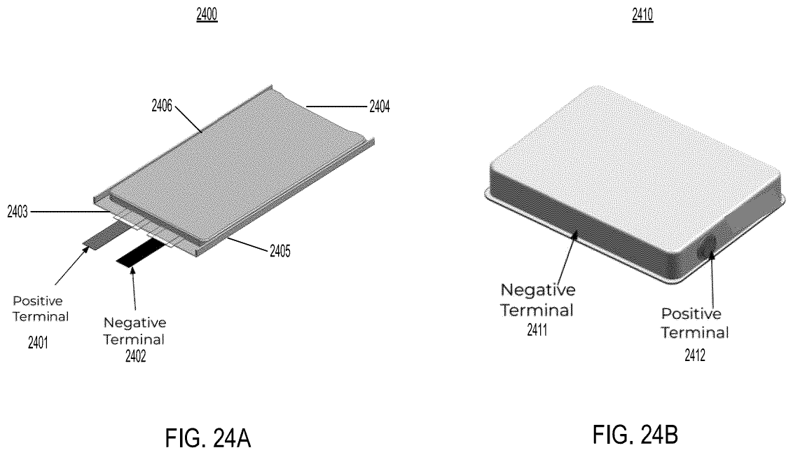

It may also be appreciated that, in providing a display device, a variety of battery (or “battery cell”) designs may be utilized. FIG. 24A illustrates a battery cell 2400 having a “conventional” design, according to an example. In some examples, a battery cell 2400 may include (both) a positive terminal 2401 and a negative terminal 2402 on one side of the battery cell 2400. In some examples, the positive terminal 2401 and the negative terminal 2402 may be located on a front side 2403 of the battery cell 2400. In other examples, the positive terminal 2401 and the negative terminal 2402 may be located on a rear side 2404 of the battery cell 2400. In some instances, this arrangement may be referred to as a “pouch-type” design.

In some examples, a pouch-type arrangement (e.g., as illustrated in FIG. 24A), when utilized in a tapered temple arm design, may make it difficult to provide an electrical connection to another component, such as a battery management unit (BMU). In addition, in some examples, it may be inefficient to place the positive terminal 2401 and the negative terminal 2402 on a first side 2405 or a second side 2406, as it may make it difficult to couple the positive terminal 2401 and the negative terminal 2402 with other device components.

However, it may be noted that alternate battery cell designs may also be available. FIG. 24B illustrates a “metal-encased” battery cell 2410, according to an example. In some examples, the metal-encased battery cell 2410 may utilize an enclosure (or encasing) as a first terminal 2411 (e.g., a negative terminal), while providing a second terminal 2412 (e.g., a positive terminal) at a particular location on the metal-encased battery cell 2410. In some examples, the second terminal 2412 may be made available on one side of the battery cell (e.g., on a front side).

In some examples, providing a terminal via a use of an encasing may make the terminal more broadly available, and in some instances (and discussed further below), may make it easier to provide an electrical connection with another electrical component (e.g., a battery management unit (BMU)) during assembly. In some instances, use of a metal-encased battery, such as the metal-encased battery 2410, may also increase battery life and thereby increase device runtime for an associated device.

Systems and methods as described herein may be directed to providing a battery management unit (BMU) in one or more spaces between a battery cell and an edge of a temple arm on smart glasses. In particular, in some examples, systems and methods as described may utilize one or more remaining spaces in between a side of a temple arm and an edge of a metal-encased battery unit to house a battery management unit (BMU).

In some examples, and often typically, a battery cell may have a rectangular design. These examples may include conventional battery designs and metal-encased battery designs. In such instances, when implemented in conjunction with a tapered temple arm design, there may remain an empty space between an edge of the battery and side of the tapered temple arm. As used herein, this empty space associated with a tapered temple arm design may be referred to as a “remaining space” of a tapered temple arm design. In some instance, this remaining space may take the shape of a trapezoid, rectangle, square, parallelogram, or triangle shape.

In some examples, the systems and methods described may improve performance of a display device (e.g., a pair of wearable smart glasses). In particular, in some examples and as will be discussed further below, compared to a front-loaded battery management unit (BMU) architecture (e.g., as shown in FIG. 24A), an architecture as described herein may increase available battery power by approximately ten percent (10%). In some examples, this may be facilitated by a large battery cell that may be housed in the additional space that may be provided, and which otherwise would have been occupied in a front-loaded architecture.

In some examples, the system and methods described herein may include an eyewear frame comprising a projector to emit display light associated with a display image; a plurality of lenses to enable a viewing user to view the display image; and a plurality of temple arms, each of the plurality of temple arms comprising at least one battery cell and at least one battery management unit (BMU) communicatively coupled to the battery cell to manage charging aspects of the battery cell, wherein the battery management may be located adjacent to the battery cell in a space between an edge of a temple arm and a side of the battery cell. In some examples, one battery management unit (BMU) of a plurality of battery management units (BMUs) may manage a (dedicated) cell of a plurality of battery cells, while in other examples, one battery management unit (BMU) may manage multiple battery cells of the plurality of battery cells. In some examples, the battery cell may be a metal-encased battery cell and the space between an edge of a temple arm and a side of the battery cell may have a trapezoidal shape. In some examples, the coupling of the battery management unit (BMU) to the battery cell may run parallel to a length of the tapered temple arm and the battery management unit (BMU) includes a flex portion that extends from a side of the battery management unit (BMU). In some examples, the systems and methods may include a battery cell that may utilize a connector to facilitate a positive connection and an encasing of the battery cell to facilitate a negative connection

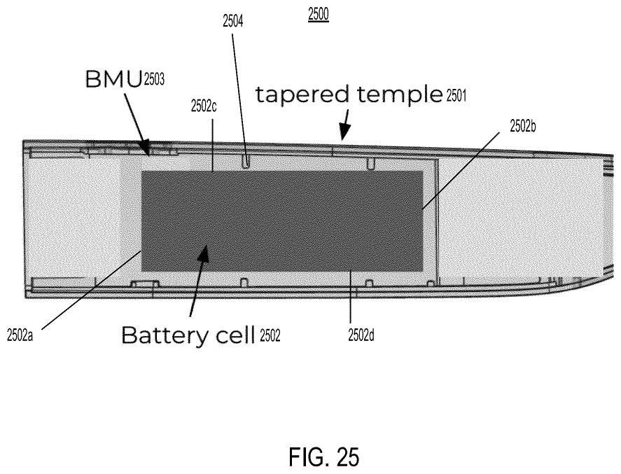

FIG. 25 illustrates a display device arrangement 2500 having a tapered temple arm 2501 design including a metal-encased battery cell 2502 and a battery management unit (BMU) 2503, according to an example. In some examples, the battery management unit (BMU) 2503 may be located adjacent and electrically coupled to the metal-encased battery cell 2502. In particular, in some examples, the battery management unit (BMU) 2503 may be located on a side of the metal-encased battery cell 2502 where a remaining space may be available.

So, in the example illustrated in FIG. 25, the metal-encased battery cell 2502 may include a front portion 2502a, a back portion 2502b, a first side portion 2502c, and a second side portion 2502d. In conventional tapered temple arm arrangements, the battery management unit (BMU) 2503 may often be located on adjacent to the front portion 2502a or the back portion 2502b of the metal-encased battery cell 2502. Accordingly, in some examples, a coupling of the battery management unit (BMU) 2503 to the metal-encased battery cell 2502 may run perpendicular to the length of the tapered temple arm 2501.

As shown in FIG. 25, a design of the tapered temple arm 2501 may provide a trapezoidal remaining space 2504 near the first side portion 2502c of the metal-encased battery cell 2502. In some examples, the battery management unit (BMU) 2503 may be located in the remaining space 2504 in between the first side portion 2502c of the metal-encased battery cell 2502 and an edge of the tapered temple arm 2501. Accordingly, in some examples, it may be said that the coupling of the battery management unit (BMU) 2503 to the metal-encased battery cell 2502 may run parallel to or “follow” the length of the tapered temple arm 2501. In some instances, this coupling of the of the battery management unit (BMU) 2503 to the metal-encased battery cell 2502 may also be referred to as a “sideways” coupling.

It may be appreciated that by utilizing a sideways coupling and a remaining space between a tapered temple arm and a metal-encased battery cell, examples provided herein may offer a more efficient fitting of components within a tapered temple arm of a display device (e.g., a pair of smart glasses). It may further be appreciated that, as described further below, such an arrangement may typically be offered via use of a metal-encased battery cell, as the flexibility offered by the location of terminals in a metal-encased battery cell may not be available with a conventional, “pouch” battery cell.

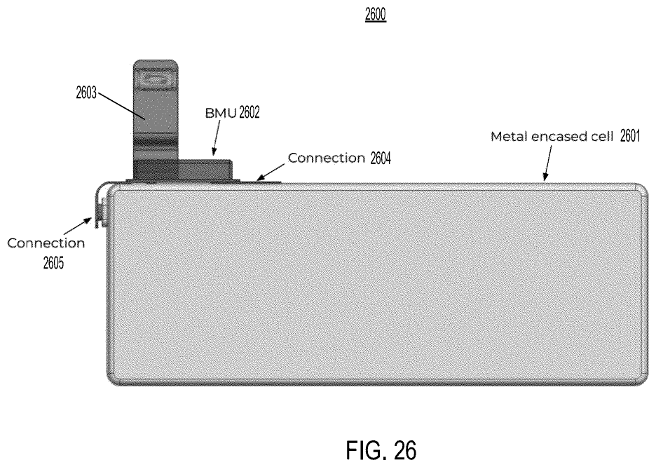

FIG. 26 illustrates a display device arrangement 2600 having a metal-encased battery cell 2601 and a battery management unit (BMU) 2602. In some examples, the battery management unit (BMU) 2602 may include one or more structured, electrically-coupled layers, according to an example. In some examples, the structured, electrically-coupled layers of the battery management unit (BMU) 2602 may include, among other things, a printed circuit board (PCB), wherein one or more electronic components, such as a flexible printed circuit (FPC) may be coupled to the printed circuit board (PCB) (e.g., via surface mount technologies). In some examples, these electronics components may be included in a “flex” (or flexible) portion 2603. It may be appreciated that the flex portion 2603 may not necessarily extend or “exit” off a side of the battery management unit (BMU) 2602 (as shown), but instead may also be, for example, angled and/or bent in any manner that may be suitable for an efficient fitting of these components within a tapered temple arm of a display device.

In some examples, the battery management unit (BMU) 2602 may further include one or more connectors for coupling to a positive terminal and a negative terminal of the metal-encased battery cell 2601. In particular, in some examples, a connection with a negative terminal may be made at a first connection 2604 and a connection with a positive terminal may be made at a second connection 2605.

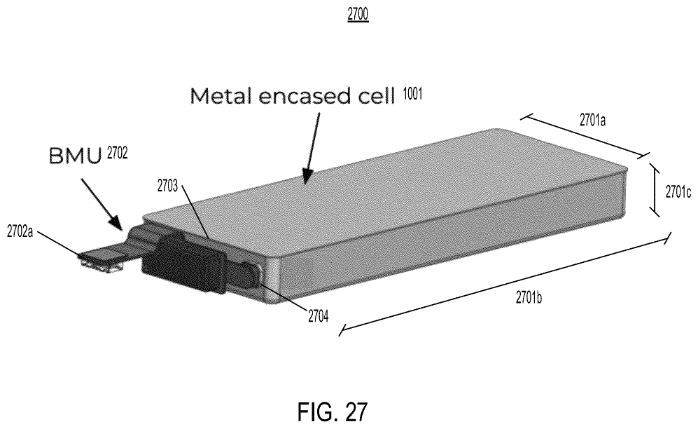

FIG. 27 illustrates a display device arrangement 2700 having a metal-encased battery cell 2701 and a battery management unit (BMU) 2702, according to an example. In some examples, a first (e.g., negative) connection may be made between the metal-encased battery cell 2701 and the battery management unit (BMU) 2702 along a first (e.g., front) side 2703 of the metal-encased battery cell 2701. Also, in some examples, a second (positive) connection may be made between the metal-encased battery cell 2701 and the battery management unit (BMU) 2702 at a first terminal 2704 of the metal-encased battery cell 2701.

As illustrated in FIG. 27, in some examples, the battery management unit (BMU) 2702 may include one or more electrically coupled elements that may extend away from the first side 2703 of the metal-encased battery cell 2701. For example, the battery management unit (BMU) 2702 may include a flex portion (as described above) that may include, among other things, a printed circuit board (PCB) 2702a. In some examples, the flex portion including the printed circuit board (PCB) 2702a may extend or “exit” away from the first side 2703 of the metal-encased battery cell 2701.

It may be appreciated that, in some examples, the metal-encased battery cell 2701 may have any dimensions that may be suitable and/or necessary to operate in particular settings. For example, in some instances, the metal-encased battery cell 2701 may have any dimensions that may be sized to fit into a temple arm of a pair of wearable glasses. So, in some examples, a width 2701a of the metal-encased battery cell 2701 may be five (5) to fifteen (15) millimeters (mm), and a length 2701b of the metal-encased battery cell 2701 may be twenty (20) to fifty (50) millimeters (mm). In some examples, a length to width ratio of the metal-encased battery cell 2701 may be greater than or equal to 1.5. Also, in some examples, a thickness 2701c of the metal-encased battery cell 2701 may be three (3) to five (5) millimeters.

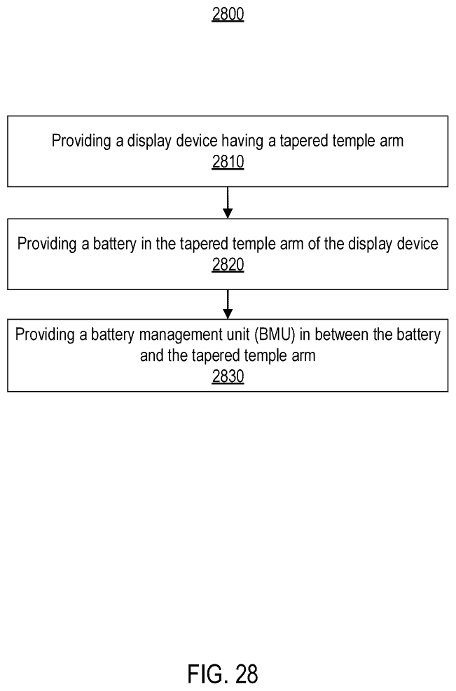

FIG. 28 illustrates a method 2800 for providing a battery management unit (BMU) in one or more spaces between a battery cell and an edge of a temple arm on smart glasses, according to an example. The method 2800 is provided by way of example, as there may be a variety of ways to carry out the method described herein. Each block shown in FIG. 28 may further represent one or more processes, methods, or subroutines, and one or more of the blocks may include machine-readable instructions stored on a non-transitory computer-readable medium and executed by a processor or other type of processing circuit to perform one or more operations described herein. In some examples, the method 2800 may be executed or otherwise performed by other systems, or a combination of systems.

Reference is now made with respect to FIG. 28. At 2810, the method may include providing a display device having a tapered temple arm. In some examples, the display device may be a pair of wearable smart glasses.

At 2820, the method may include providing a battery in the tapered temple arm of the display device. In some examples, the battery may be a metal-encased battery cell.

At 2830, the method may include providing a battery management unit (BMU) in between the battery and the tapered temple arm. In some examples, the battery management unit may be located in a remaining space that may be trapezoidal in shape.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims—and their equivalents—in which all terms are meant in their broadest reasonable sense unless otherwise indicated.

1. A method for communicatively coupling components of a display device, comprising:
printing a conductive trace onto a carrier;
mounting a light-emitting diode (LED) onto the carrier; and
attaching a flexible printed circuit (FPC) to the carrier, wherein the light-emitting diode (LED) is communicatively coupled to the flexible printed circuit (FPC) via the conductive trace.

2. The method of claim 1, wherein the light-emitting diode (LED) is an infrared (IR) light-emitting diode (LED).

3. The method of claim 2, wherein the conductive trace is printed via laser direct structuring (LDS).

4. The method of claim 3, wherein the light-emitting diode (LED) is mounted via surface-mount technology (SMT).

5. The method of claim 4, wherein the light-emitting diode (LED) is mounted utilizing a slanted profile.

6. The method of claim 1, wherein the light-emitting diode (LED) is mounted utilizing a flat profile.

7. The method of claim 1, wherein the flexible printed circuit (FPC) is approximately twenty-five (25) to thirty (30) millimeters in length.

8. An apparatus, comprising:
a carrier including a conductive trace, wherein the conductive trace is printed onto the carrier;
a light-emitting diode (LED) mounted onto the carrier; and
a flexible printed circuit (FPC) attached to the carrier, wherein the light-emitting diode (LED) is communicatively coupled to the flexible printed circuit (FPC) via the conductive trace.

9. The apparatus of claim 8, wherein the light-emitting diode (LED) is an infrared (IR) light-emitting diode (LED).

10. The apparatus of claim 9, wherein the conductive trace is printed via laser direct structuring (LDS).

11. The apparatus of claim 10, wherein the light-emitting diode (LED) is mounted via surface-mount technology (SMT).

12. The apparatus of claim 11, wherein the light-emitting diode (LED) is mounted utilizing a slanted profile.

13. The apparatus of claim 8, wherein the light-emitting diode (LED) is mounted utilizing a flat profile.

14. The apparatus of claim 8, wherein the flexible printed circuit (FPC) is approximately twenty-five (25) to thirty (30) millimeters in length.

15. A display system, comprising:
an imaging device;
a console; and
a near-eye display, the near-eye display comprising:
a carrier including a conductive trace, wherein the conductive trace is printed onto the carrier;
a light-emitting diode (LED) mounted onto the carrier; and
a flexible printed circuit (FPC) attached to the carrier, wherein the light-emitting diode (LED) is communicatively coupled to the flexible printed circuit (FPC) via the conductive trace.

16. The display system of claim 15, wherein the light-emitting diode (LED) is an infrared (IR) light-emitting diode (LED).

17. The display system of claim 16, wherein the conductive trace is printed via laser direct structuring (LDS).

18. The display system of claim 17, wherein the light-emitting diode (LED) is mounted via surface-mount technology (SMT).

19. The display system of claim 15, wherein the light-emitting diode (LED) is mounted utilizing a slanted profile.

20. The display system of claim 15, wherein the light-emitting diode (LED) is mounted utilizing a flat profile.
